(19) United States
(12) Patent Application Publication
(10) Pub. No.: US 2026/0198181 A1
(43) Pub. Date: Jul. 9, 2026

(54) DISPLAY DEVICE AND ELECTRONIC DEVICE INCLUDING THE SAME

(71) Applicant: Samsung Display Co., Ltd., Yongin-si (KR)

(72) Inventors: JANGMI KANG, Yongin-si (KR); JINSEON KWAK, Yongin-si (KR); KEONMIN OH, Yongin-si (KR); YUNJANG PYUN, Yongin-si (KR)

(21) Appl. No.: 19/443,675

(22) Filed: Jan. 8, 2026

(30) Foreign Application Priority Data
Jan. 8, 2025 (KR) 10-2025-0002803

(51) Int. Cl. H10K 59/121; H10K 59/131

(52) U.S. Cl. CPC H10K 59/1213; H10K 59/131

(57) ABSTRACT

A display device includes a substrate including a display area and a non-display area, a plurality of pixels arranged in the display area, a first channel portion arranged in the non-display area on the substrate and configured to provide a data voltage to a first pixel among the plurality of pixels, a second channel portion arranged in the non-display area, spaced apart from the first channel portion in a plan view, and configured to provide the data voltage to a second pixel, which is different from the first pixel, among the plurality of pixels, and a first data power voltage line arranged between the first channel portion and the second channel portion in the plan view, overlapping the first channel portion and the second channel portion in the plan view, and electrically connected to each of the first channel portion and the second channel portion.

This application claims priority to Korean Patent Application No. 10-2025-0002803, filed on January 8, 2025, and all the benefits accruing therefrom under 35 U.S.C. §119, the content of which in its entirety is herein incorporated by reference.

### BACKGROUND

### FIELD

Embodiments relate to a display device and an electronic device including the same. More particularly, the embodiments relate to the display device for high-resolution and the electronic device including the same

### DESCRIPTION OF THE RELATED ART

Generally, a display device includes a display panel and a driver for the display panel. The display panel includes a plurality of gate lines, a plurality of data lines, and a plurality of pixels. The driver for the display panel includes a gate driver that provides gate signals to the plurality of gate lines, a data driver that provides data voltages to the data lines, and a driving controller that controls the gate driver and the data driver. The data driver includes a plurality of channel portions that output data voltages to the plurality of data lines of the display panel.

Recently, in order to implement high-resolution display devices, ultra-small light-emitting elements that are independently grown on a substrate including silicon or glass are being manufactured. As high-resolution display devices are implemented, the PPI (pixels per inch), which represents the density of pixels in the display device, increases, and the number of channel portions included in the data driver also increases. Accordingly, research is being conducted to efficiently arrange the data driver in the display device.

### SUMMARY

Embodiments provide a display device with improved display quality.

Embodiments provide an electronic device including the display device.

A display device according to an embodiment includes a substrate including a display area and a non-display area adjacent to the display area, a plurality of pixels arranged in the display area on the substrate, a first channel portion arranged in the non-display area on the substrate and configured to provide a data voltage to a first pixel among the plurality of pixels, a second channel portion arranged in the non-display area on the substrate, spaced apart from the first channel portion in a plan view, and configured to provide the data voltage to a second pixel, which is different from the first pixel, among the plurality of pixels, and a first data power voltage line arranged between the first channel portion and the second channel portion in the plan view, overlapping the first channel portion and the second channel portion in the plan view, and electrically connected to each of the first channel portion and the second channel portion.

In an embodiment, the first data power voltage line may extend along a first direction, and the second channel portion may be spaced apart from the first channel portion in a second direction crossing the first direction.

In an embodiment, the display device may further include a third channel portion spaced apart from the second channel portion in the second direction, disposed opposite to the first channel portion with respect to the second channel portion, and configured to provide the data voltage to a third pixel, which is different from the first pixel and the second pixel, among the plurality of pixels and a second data power voltage line arranged between the second channel portion and the third channel portion in the plan view, and electrically connected to each of the second channel portion and the third channel portion.

In an embodiment, a first data power voltage may be configured to be applied to the first data power voltage line, and a second data power voltage, which has a different level from the first data power voltage, may be configured to be applied to the second data power voltage line.

In an embodiment, the second data power voltage line may overlap the second channel portion and the third channel portion in the plan view.

In an embodiment, each of the first data power voltage line and the second data power voltage line may be provided in plurality, and the first data power voltage line and the second data power voltage line may be alternately arranged along the second direction.

In an embodiment, the second channel portion and the third channel portion may be symmetrical with respect to the second data power voltage line.

In an embodiment, the display device may further include at least one transistor arranged in the display area, the at least one transistor each including a gate electrode and source and drain electrodes arranged on the gate electrode and a light-emitting element arranged in the display area, electrically connected to each of the at least one transistor, and including a pixel electrode, a light-emitting layer, and a common electrode sequentially stacked. The first data power voltage line and the second data power voltage line may be arranged, in a cross-sectional view, between the pixel electrode and the source and drain electrodes.

In an embodiment, the display device may further include a gamma reference voltage generator arranged in the non-display area on the substrate and configured to provide a gamma reference voltage to each of the first channel portion and the second channel portion, at least one first gamma voltage line extending from the gamma reference voltage generator toward the first channel portion, at least one second gamma voltage line extending from the gamma reference voltage generator toward the second channel portion, and at least one third gamma voltage line extending from the gamma reference voltage generator toward the third channel portion.

In an embodiment, the at least one first gamma voltage line may overlap the first channel portion in the plan view, the at least one second gamma voltage line may overlap the second channel portion in the plan view, and the at least one third gamma voltage line overlaps the third channel portion in the plan view.

In an embodiment, the display device may further include at least one transistor arranged in the display area, the at least one transistor each including a gate electrode, and source and a drain electrodes arranged on the gate electrode and a light-emitting element arranged in the display area, electrically connected to each of the at least one transistor, and including a pixel electrode, a light-emitting layer, and a common electrode sequentially stacked. The first gamma voltage line, the second gamma voltage line, and the third gamma voltage line may be arranged, in a cross-sectional view, between the pixel electrode and the source and the drain electrodes.

In an embodiment, each of the first gamma voltage line, the second gamma voltage line, and the third gamma voltage line may be arranged between the first data power voltage line and the second data power voltage line in the plan view.

In an embodiment, the first channel portion and the second channel portion may be symmetrical with respect to the first data power voltage line.

In an embodiment, the first pixel may include a first sub-pixel configured to emit light of a first color, a second sub-pixel configured to emit light of a second color different from the first color, and a third sub-pixel configured to emit light of a third color different from the second color. The first channel portion may include a first channel amplifier arranged in the non-display area adjacent to the display area on the substrate and configured to output the data voltage to the first sub-pixel, a second channel amplifier spaced apart from the first channel amplifier in a first direction and configured to output the data voltage to the second sub-pixel, and a third channel amplifier spaced apart from the second channel amplifier in the first direction and configured to output the data voltage to the third sub-pixel.

In an embodiment, the first channel portion may further include a first digital-to-analog converter arranged between the first channel amplifier and the second channel amplifier, in the plan view, a first decoder arranged between the first digital-to-analog converter and the second channel amplifier, in the plan view, a second digital-to-analog converter arranged between the second channel amplifier and the third channel amplifier, in the plan view, a second decoder arranged between the second digital-to-analog converter and the third channel amplifier, in the plan view, a third digital-to-analog converter located in the first direction from the third channel amplifier, in the plan view, and a third decoder located in the first direction from the third digital-to-analog converter in the plan view.

In an embodiment, a length of the first channel amplifier in the first direction may be greater than a sum of a length of the first digital-to-analog converter in the first direction and a length of the first decoder in the first direction.

In an embodiment, a length of the first channel amplifier in the first direction, a length of the second channel amplifier in the first direction, and a length of the third channel amplifier in the first direction may be equal to each other.

In an embodiment, the first data power voltage line may be arranged on the first channel portion and the second channel portion.

An electronic device according to an embodiment includes a processor configured to output an input image data and an input control signal and a display device configured to drive based on the input image data and the input control signal. The display device according to an embodiment includes a substrate including a display area and a non-display area adjacent to the display area, a plurality of pixels arranged in the display area on the substrate, a first channel portion arranged in the non-display area on the substrate and configured to provide a data voltage to a first pixel among the plurality of pixels, a second channel portion arranged in the non-display area on the substrate, spaced apart from the first channel portion in a plan view, and configured to provide the data voltage to a second pixel, which is different from the first pixel, among the plurality of pixels, and a first data power voltage line arranged between the first channel portion and the second channel portion in the plan view, overlapping the first channel portion and the second channel portion in the plan view, and electrically connected to each of the first channel portion and the second channel portion.

In an embodiment, the electronic device may be one selected from a group consisted of a virtual reality (VR) device, an augmented reality (AR) device, a mixed reality (MR) device, an extended reality (XR) device, a head-mounted device, a mobile phone, a video phone, a smartphone, a smart pad, a smart watch, a tablet PC, a vehicle display, a television, a monitor, a notebook computer, or a vehicle.

In a display device according to embodiments of the present disclosure, one of a data power voltage line may be electrically connected to each of two channel portions. In addition, one of the data power voltage lines may extend in a first direction and may overlap with the two channel portions in a plan view. In addition, data power voltage lines to which a high data power voltage is applied and data power voltage lines to which a low data power voltage is applied may be alternately arranged along a second direction. Accordingly, the number of channel portions electrically connected to a plurality of pixels in the display device may be increased, and thus, the number of pixels electrically connected to each of the channel portions may be increased. Therefore, the display for high-resolution device may be implemented.

In an electronic device according to embodiments of the present disclosure, a processor for driving the display device may be included, and a housing for accommodating the display device may be provided. Accordingly, the electronic device may be provided that can operate stably and display high-resolution images.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to an embodiment of the present disclosure.

FIG. 2 is a block diagram illustrating the display device of FIG. 1.

FIG. 3 is a circuit diagram illustrating a first sub-pixel included in the display device of FIG. 1.

FIG. 4 is a cross-sectional view illustrating a portion of the display device of FIG. 1.

FIG. 5 is a block diagram illustrating a gamma reference voltage generator and a data driver of FIG. 1.

FIG. 6 is a plan view illustrating a first channel portion of FIG. 5.

FIG. 7 is a plan view illustrating a data driver of FIG. 1.

FIG. 8 is a block diagram illustrating an electronic device according to an embodiment of the present disclosure.

FIG. 9 is a view illustrating an example in which the electronic device of FIG. 8 is implemented as a smartphone.

FIG. 10 is a view illustrating an example in which the electronic device of FIG. 8 is implemented as a head-mounted device.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

It will be understood that when an element is referred to as being “connected to” another element, it can be directly connected to the other element or intervening elements may be present therebetween. In contrast, when an element is referred to as being “directly connected to” another element, there are no intervening elements present.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Hereinafter, display devices in accordance with embodiments will be described in more detail with reference to the accompanying drawings. The same reference numerals are used for the same components in the drawings, and redundant descriptions of the same components will be omitted.

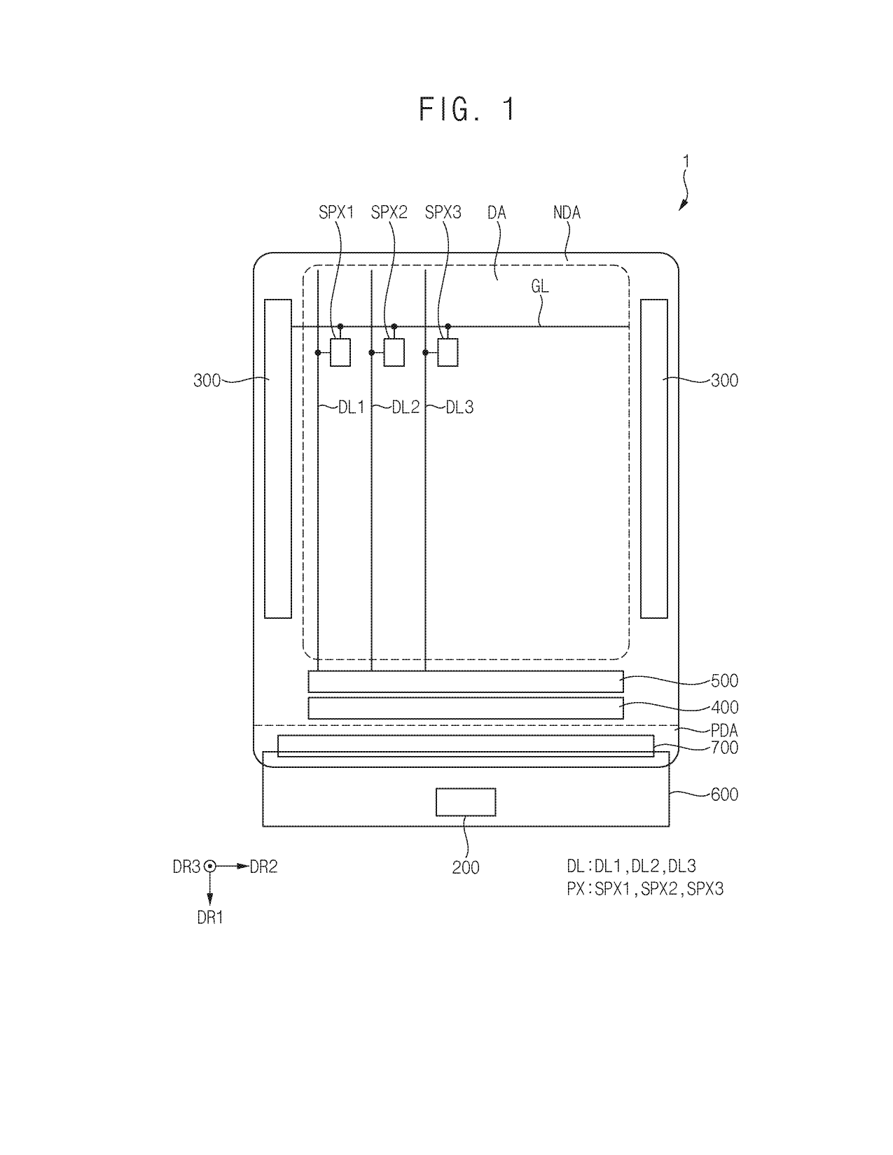

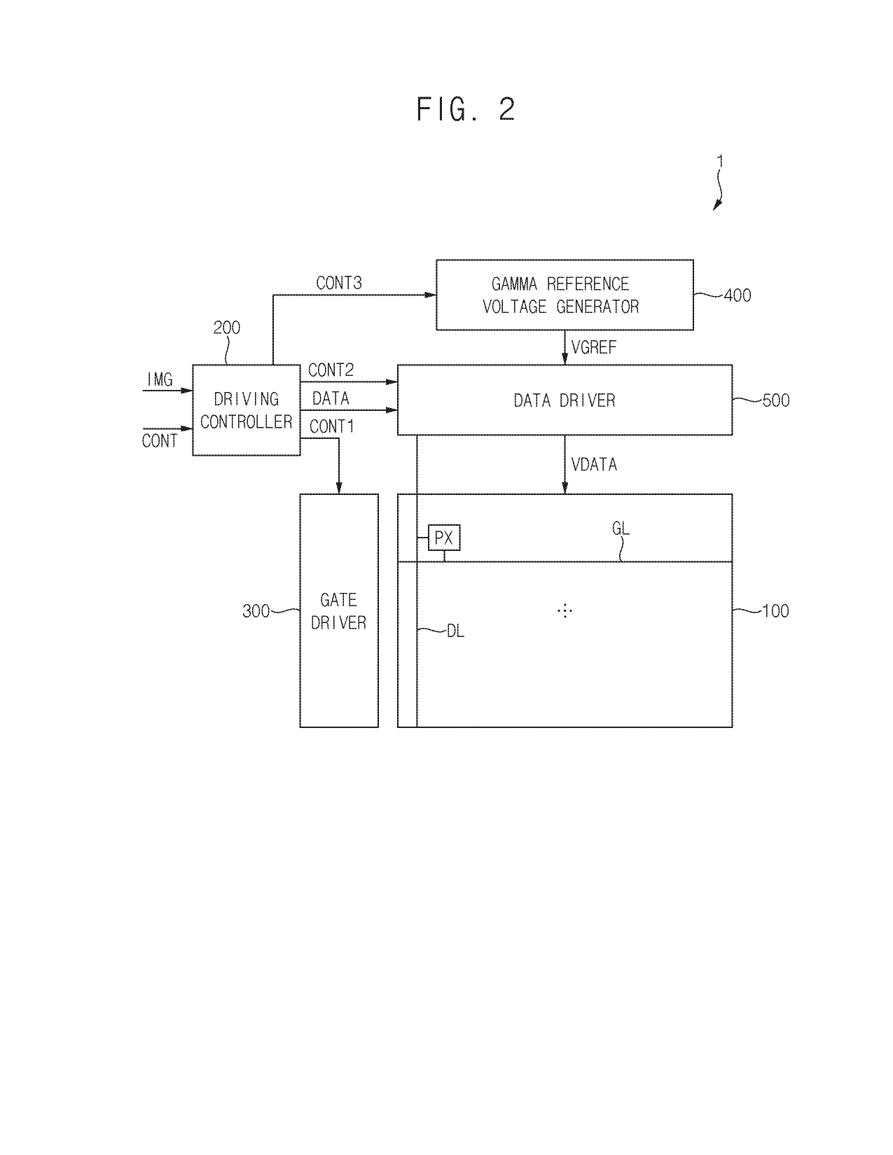

FIG. 1 is a block diagram illustrating a display device according to an embodiment of the present disclosure. FIG. 2 is a block diagram illustrating the display device of FIG. 1.

Referring to FIGS. 1 and 2, a display device 1 may include a display area DA, a non-display area NDA, and a pad area PDA. The display device 1 may include a substrate SUB. Accordingly, the substrate SUB may include the display area DA, the non-display area NDA, and the pad area PDA.

The display device 1 may include a display panel 100 and a display panel driver. The display panel driver may include a driving controller 200, a gate driver 300, a gamma reference voltage generator 400, and a data driver 500. In addition, the display panel 100 may include a display area DA, a non-display area NDA, and a pad area PDA.

In the disclosure, a plane may be defined by a first direction DR1 and a second direction DR2 crossing the first direction DR1. For example, the second direction DR2 may be perpendicular to the first direction DR1. In addition, a third direction DR3 may be perpendicular to the plane.

The display area DA may be defined as an area for displaying images. A plurality of pixels PX may be arranged in the display area DA. For example, the display panel 100 may include the plurality of pixels PX. A plurality of gate lines GL and a plurality of data lines DL may be arranged in the display area DA. The display panel driver may be arranged in the non-display area NDA and the pad area PDA.

The plurality of pixels PX may be arranged in a matrix form including a plurality of pixel rows and a plurality of pixel columns. The plurality of pixels PX may be arranged along the first direction DR1 and the second direction DR2. One pixel among the plurality of pixels PX may include sub-pixels, which emit light of different colors. For example, the one pixel may include a first sub-pixel SPX1, which emits light of a first color, a second sub-pixel SPX2, which emits light of a second color, and a third sub-pixel SPX3, which emits light of a third color.

In an embodiment, the light of the first color may be red light, the light of the second color may be green light, and the light of the third color may be blue light. However, the colors of light emitted by the first sub-pixel SPX1, the second sub-pixel SPX2, and the third sub-pixel SPX3 according to the embodiments of the disclosure may not be limited thereto. For example, the first sub-pixel, the second sub-pixel, and the third sub-pixel may be combined to emit magenta light, cyan light, and yellow light.

In an embodiment, each of the plurality of gate lines GL may extend along the second direction DR2. In an embodiment, each of the plurality of gate lines GL may be spaced apart from each other in the first direction DR1. In an embodiment, each of the plurality of data lines DL may extend along the first direction DR1. In an embodiment, each of the plurality of data lines DL may be spaced apart from each other in the second direction DR2.

In an embodiment, each of the plurality of pixels PX may be electrically connected to at least one among the plurality of gate lines and at least one among the plurality of data lines DL. The plurality of data lines DL may include a first data line DL1, a second data line DL2, and a third data line DL3. For example, the first sub-pixel SPX1 may be electrically connected to the first data line DL1. The second sub-pixel SPX2 may be electrically connected to the second data line DL2. The third sub-pixel SPX3 may be electrically connected to the third data line DL3.

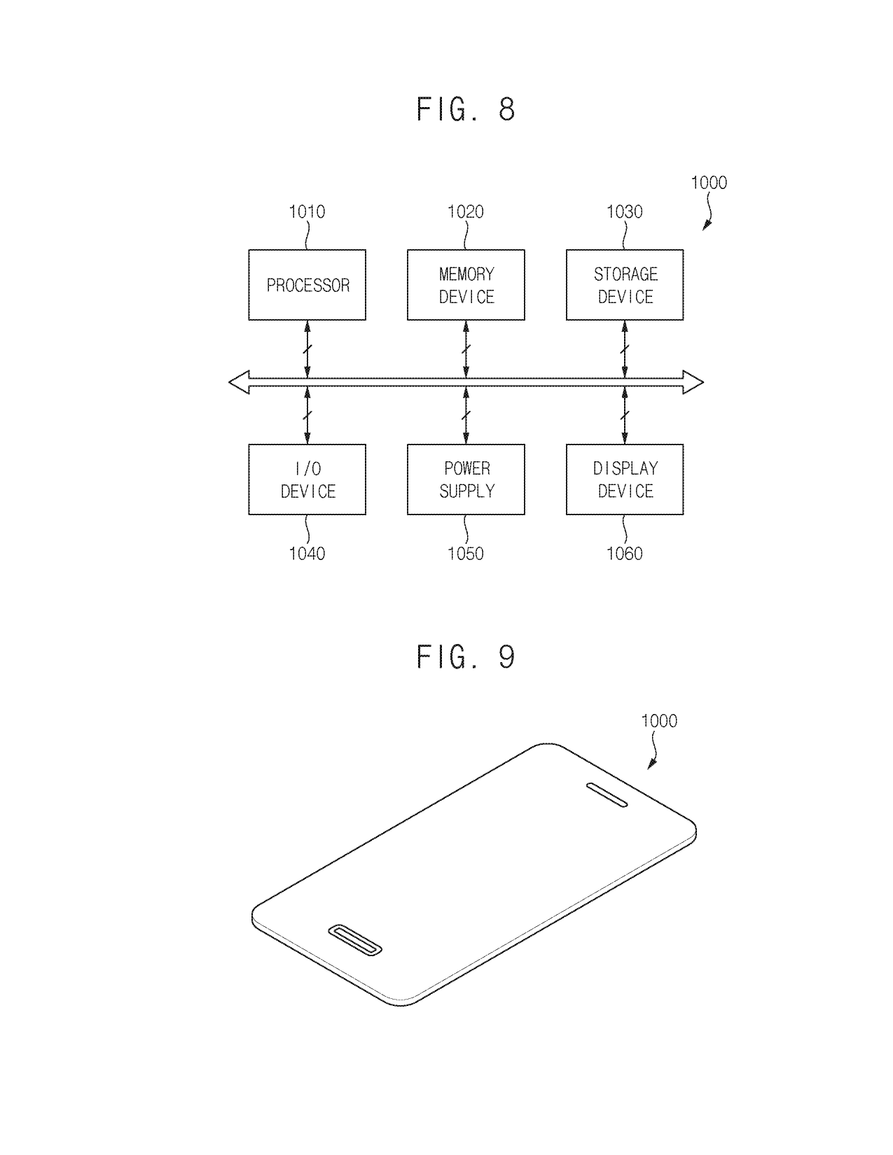

The driving controller 200 may receive input image data IMG and input control signals CONT from an external device (e.g., a processor such as a graphic processing unit GPU or a processor 1010 of FIG. 8). In an embodiment, the input image data IMG may include a red image data, a green image data, and a blue image data. In an embodiment, the input image data IMG may further include a white image data. In another embodiment, the input image data IMG may include a magenta image data, a yellow image data, and a cyan image data. The input control signals CONT may include a master clock signal and a data enable signal. The input control signals CONT may further include a vertical sync signal and a horizontal sync signal.

The driving controller 200 may generate a gate control signal CONT1, a data control signal CONT2, a gamma control signal CONT3, and a data signal DATA based on the input image data IMG and the input control signals CONT.

The driving controller 200 may generate the gate control signal CONT1 to control the operation of the gate driver 300 based on the input control signals CONT. The driving controller 200 may output the gate control signal CONT1 to the gate driver 300. For example, the gate control signal CONT1 may include a vertical start signal and a gate clock signal.

The driving controller 200 may generate the data control signal CONT2 to control the operation of the data driver 500 based on the input control signals CONT. The driving controller 200 may output the data control signal CONT2 to the data driver 500. For example, the data control signal CONT2 may include a horizontal start signal and a load signal.

The driving controller 200 may generate the data signal DATA based on the input image data IMG. In an embodiment, the driving controller 200 may output the data signal DATA to the data driver 500.

The driving controller 200 may generate the gamma control signal CONT3 to control the operation of the gamma reference voltage generator 400 based on the input control signals CONT. The driving controller 200 may output the gamma control signal CONT3 to the gamma reference voltage generator 400.

The gamma reference voltage generator 400 may generate a gamma reference voltage VGREF in response to the gamma control signal CONT3 received from the driving controller 200. The gamma reference voltage generator 400 may provide the gamma reference voltage VGREF to the data driver 500. In an embodiment, the gamma reference voltage generator 400 may be arranged in the driving controller 200 or in the data driver 500.

The data driver 500 may receive the data control signal CONT2 and the data signal DATA from the driving controller 200. The data driver 500 may receive the gamma reference voltage VGREF from the gamma reference voltage generator 400. The data driver 500 may convert the data signal DATA into analog data voltages using the gamma reference voltage VGREF. The data driver 500 may output the data voltages to each of the plurality of data lines DL.

In an embodiment, the display device 1 may further include a circuit board 600 and a pad portion 700. The circuit board 600 and the pad portion 700 may be electrically connected to each other. In an embodiment, the driving controller 200 may be arranged on the circuit board 600. However, the driving controller 200 according to the embodiments of the disclosure may not be limited thereto.

In an embodiment, the driving controller 200 may be electrically connected to each of the gate driver 300, the gamma reference voltage generator 400, and the data driver 500 through the circuit board 600 and the pad portion 700. In an embodiment, the circuit board 600 may be a printed circuit board PCB. However, the type of the circuit board 600 according to the embodiments of the disclosure may not be limited thereto.

In an embodiment, the pad portion 700 may be arranged in the pad area PDA. In an embodiment, the circuit board 600 may partially overlap the pad area PDA in a plan view. However, the number and arrangement of the pad portion 700 according to the embodiments of the disclosure may not be limited thereto. For example, the display device 1 may further include another pad portion arranged in a direction opposite to the first direction DR1 from the display area DA.

In an embodiment, the pad portion 700 may include a plurality of pad electrodes spaced apart from each other in a plan view along the second direction DR2. Accordingly, the circuit board 600 may include lead electrodes corresponding to the pad electrodes. As the pad electrodes of the pad portion 700 and the lead electrodes of the circuit board 600 come into contact with each other, the circuit board 600 and the pad portion 700 may be electrically connected.

In an embodiment, the gate driver 300 may be arranged in the non-display area NDA. For example, the gate driver 300 may be arranged in the non-display area NDA located in the second direction DR2 or in the direction opposite to the second direction DR2 from the display area DA. Specifically, two gate drivers may be arranged at both sides of the display area DA.

In an embodiment, each of the plurality of gate lines GL may extend from one among the gate drivers 300. For example, each of the plurality of gate lines GL may be alternately arranged along the first direction DR1 from the gate driver 300 located in the second direction DR2 and from the gate driver 300 located in the direction opposite to the second direction DR2 with respect to the display area DA. However, the arrangement of the gate driver 300 according to the embodiments of the disclosure may not be limited thereto. For example, one gate driver 300 may be arranged in the second direction DR2 or in the direction opposite to the second direction DR2 from the display area DA.

In an embodiment, the gamma reference voltage generator 400 and the data driver 500 may be arranged in the non-display area NDA. For example, the gamma reference voltage generator 400 and the data driver 500 may be arranged in the non-display area NDA adjacent to the pad area PDA. Specifically, the gamma reference voltage generator 400 and the data driver 500 may be arranged in the non-display area NDA located in the first direction DR1 from the display area DA.

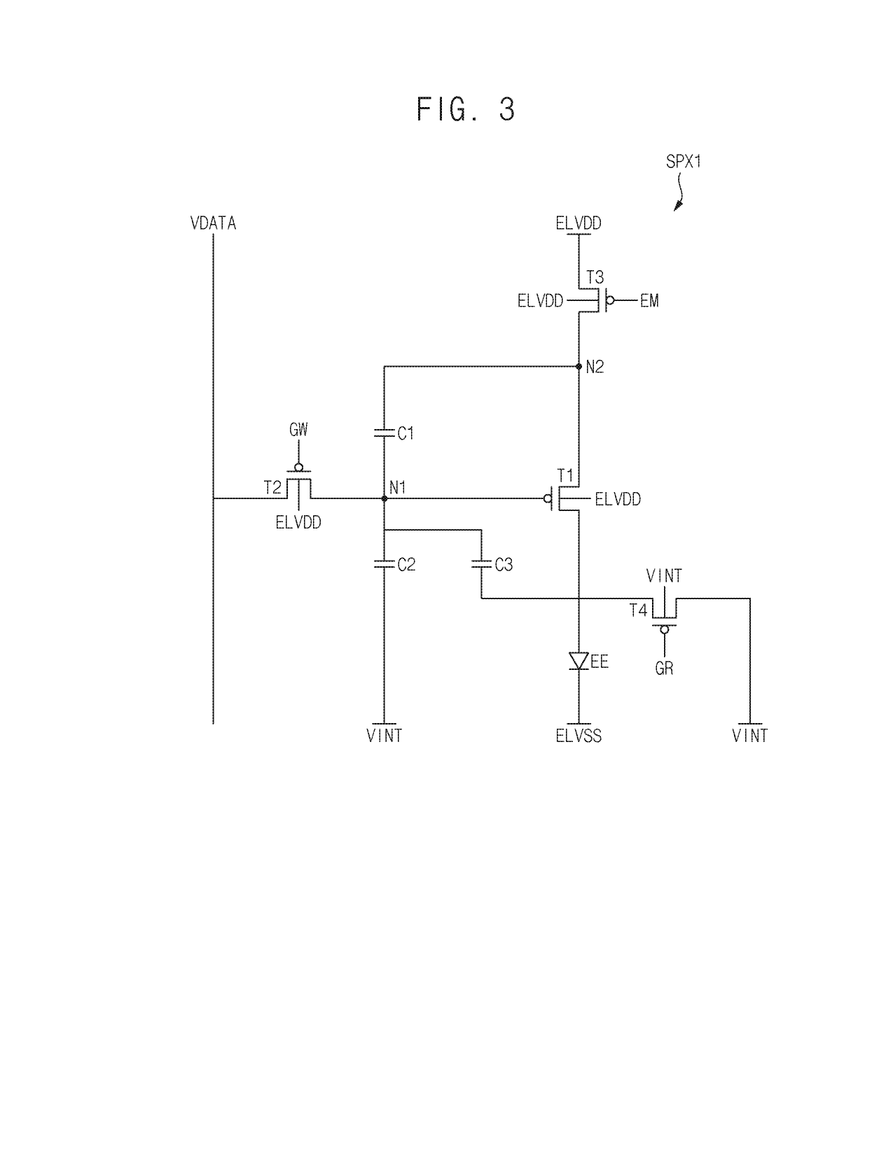

FIG. 3 is a circuit diagram illustrating a first sub-pixel included in the display device of FIG. 1.

Referring to FIG. 3, the first sub-pixel SPX1 may include a pixel circuit and a light-emitting element EE. The pixel circuit may include a first transistor T1, a second transistor T2, a third transistor T3, a fourth transistor T4, a first capacitor C1, a second capacitor C2, and a third capacitor C3. The pixel circuit may supply a driving current to the light-emitting element EE, and the light-emitting element EE may generate light based on the driving current.

The first transistor T1 may include a gate electrode connected to a first node N1, a first electrode connected to a second node N2, and a second electrode connected to the light-emitting element EE. The first transistor T1 may generate the driving current based on the voltage between the second node N2 and a first terminal of the light-emitting element EE electrically connected to the first transistor T1, that is, the voltage stored in the first capacitor C1. The first transistor T1 may supply the driving current to the light-emitting element EE.

The second transistor T2 may include a gate electrode receiving a gate write signal GW, a first electrode connected to a data voltage line (e.g., the first data line DL1 of FIG. 1), and a second electrode connected to the first node N1. Accordingly, the second transistor T2 may be turned on or off by the gate write signal GW. For example, the second transistor T2 may apply a data voltage VDATA, received from the data voltage line, to the first node N1 in response to the gate write signal GW.

The third transistor T3 may include a gate electrode receiving a light-emitting signal EM, a first electrode to which a first power voltage ELVDD is applied, and a second electrode connected to the second node N2. Accordingly, the third transistor T3 may be turned on or off by the light-emitting signal EM. For example, the third transistor T3 may apply the first power voltage ELVDD to the second node N2 in response to the light-emitting signal EM.

The fourth transistor T4 may include a gate electrode to which a gate reference signal GR is applied, a first electrode to which an initialization voltage VINT is applied, and a second electrode connected to the first terminal of the light-emitting element EE. Accordingly, the fourth transistor T4 may be turned on or off by the gate reference signal GR. For example, the fourth transistor T4 may apply the initialization voltage VINT to the second electrode of the first transistor T1 in response to the gate reference signal GR.

The first capacitor C1 may include a first electrode connected to the first node N1 and a second electrode connected to the second node N2. In an embodiment, the first capacitor C1 may store the data voltage VDATA delivered through the second transistor T2.

The second capacitor C2 may include a first terminal to which the initialization voltage VINT is applied and a second electrode connected to the first node N1. The third capacitor C3 may include a first electrode connected to the first node N1 and a second electrode connected to the first terminal of the light-emitting element EE.

The light-emitting element EE may include the first terminal (e.g., an anode terminal) and the second terminal (e.g., a cathode terminal). The first terminal of the light-emitting element EE may be electrically connected to the first transistor T1, and the second terminal may receive a second power voltage ELVSS. The light-emitting element EE may generate light having luminance corresponding to the driving current.

In an embodiment, the second power voltage ELVSS may have a voltage level different from a voltage level of the first power voltage ELVDD. For example, the voltage level of the second power voltage ELVSS may be lower than the voltage level of the first power voltage ELVDD. However, the relationship between the voltage levels of the second power voltage ELVSS and the first power voltage ELVDD according to the embodiments of the disclosure may not be limited thereto.

In an embodiment, each of the first transistor T1, the second transistor T2, the third transistor T3, and the fourth transistor T4 may be a P-type transistor. For example, each of the first transistor T1, the second transistor T2, the third transistor T3, and the fourth transistor T4 may be a polysilicon transistor.

In an embodiment, the first transistor T1 may further include a back gate electrode to which the first power voltage ELVDD is applied. In an embodiment, the second transistor T2 may further include a back gate electrode to which the first power voltage ELVDD is applied. In an embodiment, the third transistor T3 may further include a back gate electrode to which the first power voltage ELVDD is applied. In an embodiment, the fourth transistor T4 may further include a back gate electrode to which the initialization voltage VINT is applied.

However, the types of the first transistor T1, the second transistor T2, the third transistor T3, and the fourth transistor T4 according to the embodiments of the disclosure may not be limited thereto. At least one of the first transistor T1, the second transistor T2, the third transistor T3, and the fourth transistor T4 may be an N-type transistor. For example, at least one of the first transistor T1, the second transistor T2, the third transistor T3, and the fourth transistor T4 may be an oxide semiconductor transistor.

Four transistors and three capacitors are illustrated in the one sub-pixel (e.g., the first sub-pixel SPX1) shown in FIG. 3, the numbers of transistors and capacitors included in one pixel according to the embodiments of the disclosure may not be limited thereto. For example, one pixel may include three or fewer or five or more transistors, or may include two or fewer or four or more capacitors.

In addition, although only the structure of the first sub-pixel SPX1 is illustrated in FIG. 3, the second sub-pixel SPX2 may have substantially the same circuit structure as the first sub-pixel SPX1. Also, although only the structure of the first sub-pixel SPX1 is illustrated in FIG. 3, the third sub-pixel SPX3 may have substantially the same circuit structure as the first sub-pixel SPX1.

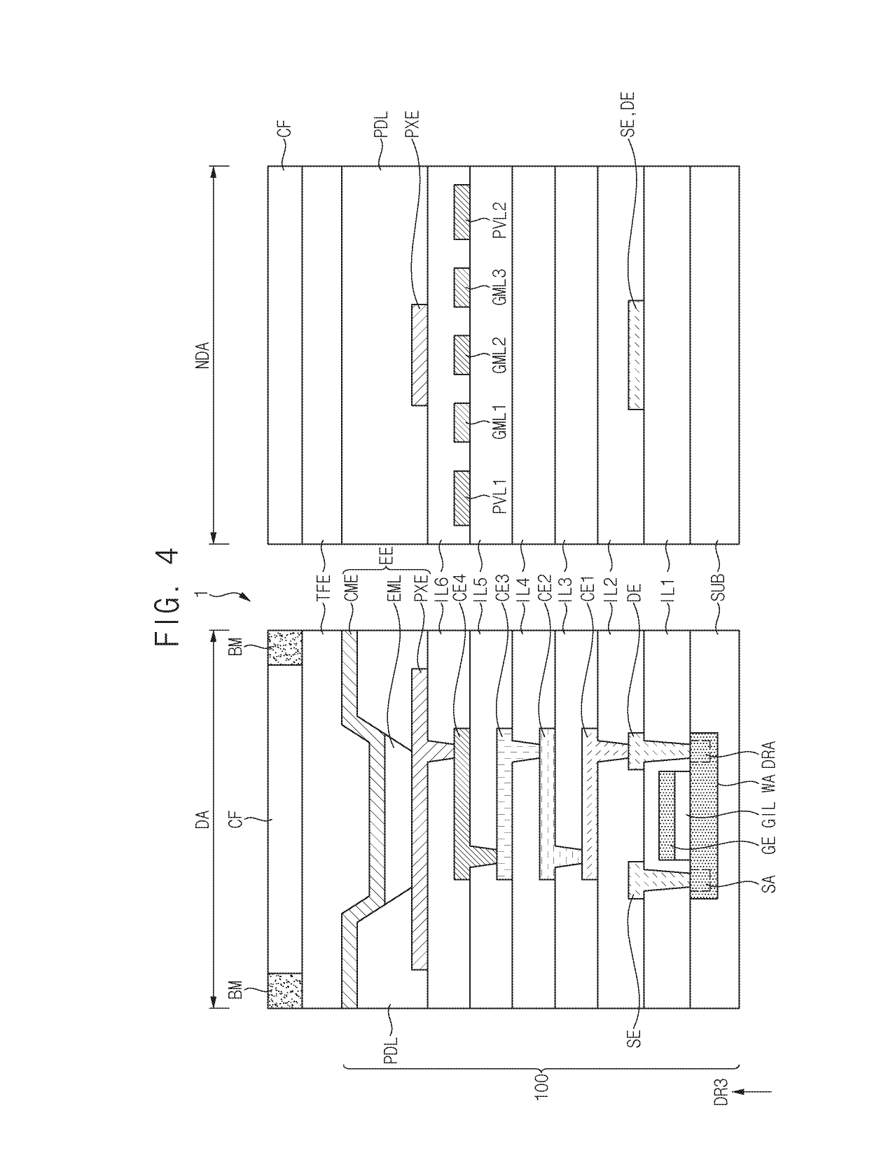

FIG. 4 is a cross-sectional view illustrating a portion of the display device of FIG. 1. For example, FIG. 4 is a cross-sectional view illustrating a portion of the display device 1 arranged in the display area DA.

Referring to FIG. 4, the display device 1 may include a substrate SUB, a gate insulating layer GIL, a gate electrode GE, a first insulating layer IL1, a source electrode SE, a drain electrode DE, a second insulating layer IL2, a first connecting electrode CE1, a third insulating layer IL3, a second connecting electrode CE2, a fourth insulating layer IL4, a third connecting electrode CE3, a fifth insulating layer IL5, a fourth connecting electrode CE4, a sixth insulating layer IL6, a pixel electrode PXE, a pixel defining layer PDL, a light-emitting layer EML, a common electrode CME, a thin-film encapsulation layer TFE, a color filter CF, and a light-blocking member BM.

The pixel electrode PXE, the light-emitting layer EML, and the common electrode CME may define a light-emitting element EE. The well area WA, source area SA, and drain area DRA of the substrate SUB, the gate electrode GE, the source electrode SE, and the drain electrode DE may define a transistor (e.g., at least one of the transistors T1, T2, T3, and T4 in FIG. 3). In addition, the components (e.g., the substrate SUB, gate insulating layer GIL, gate electrode GE, first insulating layer IL1, source electrode SE, drain electrode DE, second insulating layer IL2, first connecting electrode CE1, third insulating layer IL3, second connecting electrode CE2, fourth insulating layer IL4, third connecting electrode CE3, fifth insulating layer IL5, fourth connecting electrode CE4, sixth insulating layer IL6, pixel electrode PXE, pixel defining layer PDL, light-emitting layer EML, and common electrode CME) stacked along the third direction DR3 from the substrate SUB to the common electrode CME may define the display panel 100.

The substrate SUB may serve as a base of the display panel 100. In an embodiment, the substrate SUB may include a silicon wafer. In an embodiment, the substrate SUB may include the well area WA, the source area SA, and the drain area DRA.

In an embodiment, the well area WA is adjacent to the source area SA and the drain area DRA, and a channel area through which charge carriers move may be defined in the well area WA located between the source area SA and the drain area DRA. The well area WA may be a p-well or an n-well. The p-well may refer to a substrate in which the charge carriers are holes, and the n-well may refer to a substrate in which the charge carriers are electrons.

In an embodiment, each of the source area SA and the drain area DRA may be adjacent to edge portions of the well area WA. In an embodiment, each of the source area SA and the drain area DRA may be regions doped with an n-type dopant or a p-type dopant. For example, when the source area SA and the drain area DRA are doped with a p-type dopant, the well area WA may be an n-well. As another example, when the source area SA and the drain area DRA are doped with an n-type dopant, the well area WA may be a p-well. However, the type of the well area WA and the type and combination of dopants doped into the source area SA and the drain area DRA according to the embodiments of the disclosure are merely exemplary and may not be limited thereto.

In an embodiment, the type of the substrate SUB may not be limited thereto, and an active layer including the source area, drain area, and the channel area may be further arranged on the substrate SUB. For example, the substrate SUB may be a transparent resin substrate such as polyimide. Specifically, the polyimide substrate may include a first organic layer, a first barrier layer, and a second organic layer. As another example, the substrate SUB may include a quartz substrate (e.g., synthetic quartz substrate, F-doped quartz substrate), a calcium fluoride substrate, a soda-lime glass substrate, or a non-alkali glass substrate. These may be used alone or in combination.

The gate insulating layer GIL may be arranged on the substrate SUB. In an embodiment, the gate insulating layer GIL may overlap at least a portion of the well area WA in a plan view. For example, the gate insulating layer GIL may overlap a central portion of the well area WA in a plan view and may not overlap an edge portions of the well area WA adjacent to the source area SA and the drain area DRA. In an embodiment, the gate insulating layer GIL may not overlap the source area SA and the drain area DRA in a plan view.

The gate electrode GE may be arranged on the gate insulating layer GIL. The gate electrode GE may overlap at least a portion of the well area WA in a plan view. For example, the gate electrode GE may overlap the central portion of the well area WA in a plan view and may not overlap the edge portions of the well area WA adjacent to the source area SA and the drain area DRA. In an embodiment, the gate electrode GE may not overlap the source area SA and the drain area DRA in a plan view. A portion of the well area WA, which overlaps the gate electrode GE may be defined as the channel area.

In an embodiment, the gate electrode GE may include a conductive material. For example, the conductive material may include copper Cu, titanium Ti, aluminum Al, or molybdenum Mo. These may be used alone or in combination.

The first insulating layer IL1 may be arranged on the substrate SUB. For example, the first insulating layer IL1 may cover the gate electrode GE on the substrate SUB. In an embodiment, the first insulating layer IL1 may cover the gate electrode GE and may provide a substantially planar top surface. However, the first insulating layer IL1 according to the embodiments of the disclosure may not be limited thereto and may have a substantially uniform thickness following the profile of the gate electrode GE, and may form a step around the gate electrode GE. In an embodiment, the first insulating layer IL1 may include an inorganic insulating material and/or an organic insulating material.

The source electrode SE and the drain electrode DE may be arranged on the first insulating layer IL1. The source electrode SE and the drain electrode DE may each be electrically connected to a portion of the substrate SUB located in the source area SA and the drain area DRA, respectively. For example, the source electrode SE and the drain electrode DE may extend to the source area SA and the drain area DRA through contact holes penetrating the first insulating layer IL1 in a thickness direction (e.g., in the third direction DR3). In an embodiment, each of the source electrode SE and the drain electrode DE may include a conductive material.

The second insulating layer IL2 may be arranged on the first insulating layer IL1. For example, the second insulating layer IL2 may cover the source electrode SE and the drain electrode DE on the first insulating layer IL1. In an embodiment, the second insulating layer IL2 may cover the source electrode SE and the drain electrode DE and provide a substantially planar top surface. However, the second insulating layer IL2 according to the embodiments of the disclosure may not be limited thereto, and may have a substantially uniform thickness following the profiles of the source electrode SE and the drain electrode DE, and may form a step around the source electrode SE and the drain electrode DE. In an embodiment, the second insulating layer IL2 may include an inorganic insulating material and/or an organic insulating material.

The first connecting electrode CE1 may be arranged on the second insulating layer IL2. In an embodiment, the first connecting electrode CE1 may contact the drain electrode DE through a contact hole penetrating the second insulating layer IL2 in the thickness direction (e.g., in the third direction DR3). However, the first connecting electrode CE1 according to the embodiments of the disclosure may not be limited thereto and may contact the source electrode SE. In an embodiment, the first connecting electrode CE1 may include a conductive material.

The third insulating layer IL3 may be arranged on the first connecting electrode CE1. For example, the third insulating layer IL3 may cover the first connecting electrode CE1. In an embodiment, the third insulating layer IL3 may include an inorganic insulating material and/or an organic insulating material.

The second connecting electrode CE2 may be arranged on the third insulating layer IL3. In an embodiment, the second connecting electrode CE2 may contact the first connecting electrode CE1 through a contact hole penetrating the third insulating layer IL3 in the thickness direction (e.g., in the third direction DR3). In an embodiment, the second connecting electrode CE2 may include a conductive material.

In an embodiment, the second connecting electrode CE2 may overlap the first connecting electrode CE1 in a plan view. For example, the second connecting electrode CE2 and the first connecting electrode CE1 may form at least one capacitor in the display panel 100. However, the first connecting electrode CE1 and the second connecting electrode CE2 according to the embodiments of the disclosure may not be limited thereto and may not overlap each other in a plan view.

The fourth insulating layer IL4 may be arranged on the second connecting electrode CE2. For example, the fourth insulating layer IL4 may cover the second connecting electrode CE2. In an embodiment, the fourth insulating layer IL4 may include an inorganic insulating material and/or an organic insulating material.

The third connecting electrode CE3 may be arranged on the fourth insulating layer IL4. In an embodiment, the third connecting electrode CE3 may contact the second connecting electrode CE2 through a contact hole penetrating the fourth insulating layer IL4 in the thickness direction (e.g., in the third direction DR3). In an embodiment, the third connecting electrode CE3 may include a conductive material.

In an embodiment, the third connecting electrode CE3 may overlap the second connecting electrode CE2 in a plan view. For example, the third connecting electrode CE3 and the second connecting electrode CE2 may form at least one capacitor in the display panel 100. However, the second connecting electrode CE2 and the third connecting electrode CE3 according to the embodiments of the disclosure may not be limited thereto and may not overlap each other in a plan view.

The fifth insulating layer IL5 may be arranged on the third connecting electrode CE3. For example, the fifth insulating layer IL5 may cover the third connecting electrode CE3. In an embodiment, the fifth insulating layer IL5 may include an inorganic insulating material and/or an organic insulating material.

The fourth connecting electrode CE4 may be arranged on the fifth insulating layer IL5. In an embodiment, the fourth connecting electrode CE4 may contact the third connecting electrode CE3 through a contact hole penetrating the fifth insulating layer IL5 in the thickness direction (e.g., in the third direction DR3). In an embodiment, the fourth connecting electrode CE4 may include a conductive material.

In an embodiment, the fourth connecting electrode CE4 may overlap the third connecting electrode CE3 in a plan view. For example, the fourth connecting electrode CE4 and the third connecting electrode CE3 may form at least one capacitor in the display panel 100. However, the third connecting electrode CE3 and the fourth connecting electrode CE4 according to the embodiments of the disclosure may not be limited thereto and may not overlap each other in a plan view.

The sixth insulating layer IL6 may be arranged on the fourth connecting electrode CE4. For example, the sixth insulating layer IL6 may cover the fourth connecting electrode CE4. In an embodiment, the sixth insulating layer IL6 may include an inorganic insulating material and/or an organic insulating material.

The pixel electrode PXE may be arranged on the sixth insulating layer IL6. In an embodiment, the pixel electrode PXE may be electrically connected to the fourth connecting electrode CE4. For example, the pixel electrode PXE may contact the fourth connecting electrode CE4 through a contact hole penetrating the sixth insulating layer IL6 in the thickness direction (e.g., in the third direction DR3).

In an embodiment, the pixel electrode PXE may include metal, alloy, conductive metal oxide, conductive metal nitride, or a transparent conductive material. For example, the pixel electrode PXE may include silver Ag and indium tin oxide ITO. These may be used alone or in combination.

The pixel defining layer PDL may be arranged on the sixth insulating layer IL6. In an embodiment, the pixel defining layer PDL may partially cover the pixel electrode PXE. Specifically, the pixel defining layer PDL may define a hole, which exposes the central portion of the pixel electrode PXE and may cover the edge portion of the pixel electrode PXE. In an embodiment, the pixel defining layer PDL may include an organic insulating material. In an embodiment, the pixel defining layer PDL may further include a light-blocking material.

The light-emitting layer EML may be arranged on the pixel electrode PXE. In an embodiment, the light-emitting layer EML may be arranged within the hole of the pixel defining layer PDL. However, the light-emitting layer EML according to the embodiments of the disclosure may not be limited thereto and may cover the entirety of the pixel defining layer PDL and the pixel electrode PXE.

In an embodiment, the light-emitting layer EML may include an organic light-emitting material. The organic light-emitting material may include a low molecular weight organic compound or a high molecular weight organic compound. However, the disclosure may not be limited thereto, and the light-emitting layer EML may include a material such as quantum dots.

The common electrode CME may be arranged on the pixel defining layer PDL. In an embodiment, the common electrode CME may be arranged on the light-emitting layer EML. In an embodiment, the common electrode CME may include metal, alloy, conductive metal oxide, conductive metal nitride, or a transparent conductive material. For example, the common electrode CME may include aluminum Al, platinum Pt, silver Ag, magnesium Mg, gold Au, chromium Cr, tungsten W, titanium Ti, and the like. These may be used alone or in combination.

The thin-film encapsulation layer TFE may be arranged on the common electrode CME. In an embodiment, the thin-film encapsulation layer TFE may include an organic layer containing an organic material and at least one inorganic layer containing an inorganic material. For example, the thin-film encapsulation layer TFE may include a first inorganic layer, an organic layer, and a second inorganic layer sequentially stacked in the third direction DR3 on the common electrode CME. The thin-film encapsulation layer TFE may seal the display area DA of the display panel 100 and protect the light-emitting element EE from external contaminants.

The color filter CF may be arranged on the thin-film encapsulation layer TFE. The color filter CF may transmit only light having a specific wavelength. For example, the color filter CF may include a first color filter, which transmits light of a first color, a second color filter, which transmits light of a second color, and a third color filter, which transmits light of a third color. The first color filter, the second color filter, and the third color filter may be repeatedly arranged along the first direction DR1 and the second direction DR2.

The light-blocking member BM may be arranged on the thin-film encapsulation layer TFE. In an embodiment, the light-blocking member BM and the color filter CF may be repeatedly arranged along the first direction DR1 and the second direction DR2. Specifically, the light-blocking member BM may be arranged in a plan view between the first color filter and the second color filter. The light-blocking member BM may be arranged in a plan view between the second color filter and the third color filter. The light-blocking member BM may be arranged in a plan view between the first color filter and the third color filter.

The light-blocking member BM may block light other than light of different colors and may prevent color mixing between adjacent color filters. In an embodiment, the light-blocking member BM may include a light-blocking material. For example, the light-blocking material may include carbon black, organic pigment, and the like.

However, the laminated structures and components included in the display device 1 according to the embodiments of the disclosure may not be limited thereto. For example, the display device 1 may include three or fewer or five or more connecting electrodes stacked in the third direction DR3, or five or fewer or seven or more insulating layers stacked in the third direction DR3. For example, the display device 1 may further include a glass substrate arranged on the color filter CF, or may further include a sealing member and a filling member arranged in the non-display area NDA of FIG. 1.

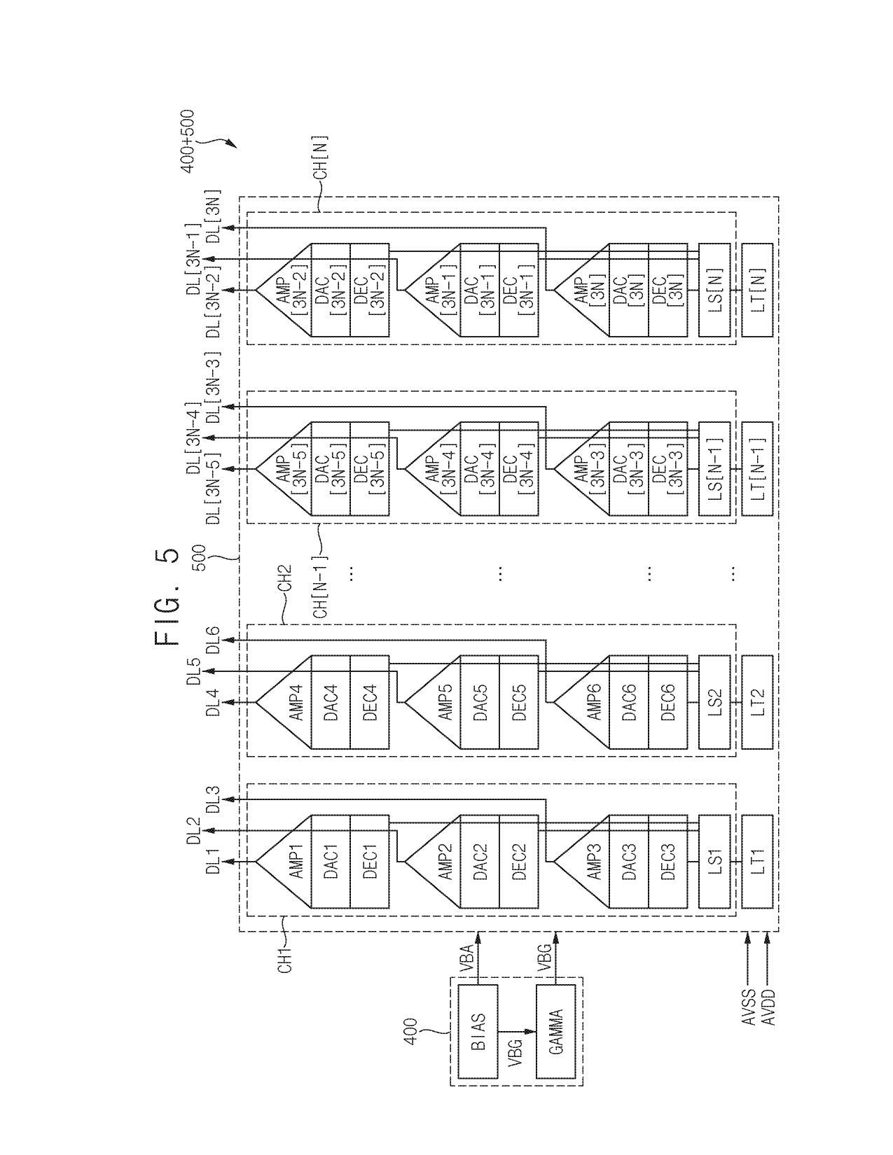

FIG. 5 is a block diagram illustrating a gamma reference voltage generator and a data driver of FIG. 1.

Referring to FIGS. 1 and 5, the data driver 500 may include a plurality of channel portions CH1, CH2, …, CH[N-1], CH[N] and a plurality of latch portions LT1, LT2, …, LT[N-1], LT[N]. For example, N may be a natural number greater than or equal to 3. The gamma reference voltage generator 400 may include a bias voltage applier BIAS and a gamma driver GAMMA.

Each of the plurality of channel portions CH1, CH2, …, CH[N-1], CH[N] may include three channel amplifiers, three digital-to-analog converters, three decoders, and a level shifter. Specifically, one channel portion may include a channel amplifier, a digital-to-analog converter, and a decoder corresponding to a first sub-pixel SPX1, which emits light of a first color, a channel amplifier, a digital-to-analog converter, and a decoder corresponding to a second sub-pixel SPX2, which emits light of a second color, and a channel amplifier, a digital-to-analog converter, and a decoder corresponding to a third sub-pixel SPX3, which emits light of a third color.

For example, the first channel portion CH1 may include a first channel amplifier AMP1, a first digital-to-analog converter DAC1, a first decoder DEC1, a second channel amplifier AMP2, a second digital-to-analog converter DAC2, a second decoder DEC2, a third channel amplifier AMP3, a third digital-to-analog converter DAC3, a third decoder DEC3, and a first level shifter LS1.

Specifically, the first channel amplifier AMP1, the first digital-to-analog converter DAC1, and the first decoder DEC1 may be electrically connected to the first data line DL1, and a data voltage VDATA may be output to the first data line DL1 through the first channel amplifier AMP1. The second channel amplifier AMP2, the second digital-to-analog converter DAC2, and the second decoder DEC2 may be electrically connected to the second data line DL2, and the data voltage VDATA may be output to the second data line DL2 through the second channel amplifier AMP2. The third channel amplifier AMP3, the third digital-to-analog converter DAC3, and the third decoder DEC3 may be electrically connected to the third data line DL3, and the data voltage VDATA may be output to the third data line DL3 through the third channel amplifier AMP3. In the disclosure, the first, second, and third sub-pixels SPX1, SPX2, SPX3 connected to the first, second, and third data lines DL1, DL2, DL3 may be collectively referred to as a first pixel.

Referring further to FIG. 5, the first channel portion CH1 may be electrically connected to the first latch portion LT1. For example, the first latch portion LT1 may receive and store digital data signals DATA from the driving controller 200. The first latch portion LT1 may transfer low-level data signals DATA to the first level shifter LS1. The first level shifter LS1 may convert the low-level data signal DATA into a high-level data signal.

The first decoder DEC1 may receive the high-level data signal output from the first level shifter LS1 and output the data signal to the first digital-to-analog converter DAC1. The first digital-to-analog converter DAC1 may convert the high-level data signal into an analog-type data voltage VDATA based on the gamma reference voltage VGREF output from the gamma reference voltage generator 400. The first channel amplifier AMP1 may output the data voltage VDATA to the first data line DL1.

For example, the second channel portion CH2 may include a fourth channel amplifier AMP4, a fourth digital-to-analog converter DAC4, and a fourth decoder DEC4, which output the data voltage VDATA to the fourth data line DL4; a fifth channel amplifier AMP5, a fifth digital-to-analog converter DAC5, and a fifth decoder DEC5, which output the data voltage VDATA to the fifth data line DL5; and a sixth channel amplifier AMP6, a sixth digital-to-analog converter DAC6, and a sixth decoder DEC6, which output the data voltage VDATA to the sixth data line DL6. The second channel portion CH2 may further include a second level shifter LS2. In the disclosure, sub-pixels connected to the fourth to sixth data lines DL4, DL5, DL6 may be referred to as a second pixel.

In an embodiment, the fourth data line DL4 may be electrically connected to a sub-pixel, which emits light of the first color, the fifth data line DL5 may be electrically connected to a sub-pixel, which emits light of the second color, and the sixth data line DL6 may be electrically connected to a sub-pixel, which emits light of the third color.

In an embodiment, the second level shifter LS2 of the second portion CH2 may be electrically connected to the second latch portion LT2. The second level shifter LS2 may have substantially the same or similar function and structure as the first level shifter LS1. The second latch portion LT2 may have substantially the same or similar function and structure as the first latch portion LT1.

For example, the (N–1)th portion CH[N-1] may include a (3N–5)th channel amplifier AMP[3N-5], a (3N–5)th digital-to-analog converter DAC[3N-5], and a (3N–5)th decoder DEC[3N-5], which output the data voltage VDATA to the (3N–5)th data line DL[3N-5]; a (3N–4)th channel amplifier AMP[3N-4], a (3N–4)th digital-to-analog converter DAC[3N-4], and a (3N–4)th decoder DEC[3N-4], which output the data voltage VDATA to the (3N–4)th data line DL[3N-4]; and a (3N–3)th channel amplifier AMP[3N-3], a (3N–3)th digital-to-analog converter DAC[3N-3], and a (3N–3)th decoder DEC[3N-3], which output the data voltage VDATA to the (3N–3)th data line DL[3N-3]. The (N–1)th portion CH[N-1] may further include an (N–1)th level shifter LS[N-1].

In an embodiment, the (3N–5)th data line DL[3N-5] may be electrically connected to a sub-pixel, which emits light of the first color, the (3N–4)th data line DL[3N-4] may be electrically connected to a sub-pixel, which emits light of the second color, and the (3N–3)th data line DL[3N-3] may be electrically connected to a sub-pixel, which emits light of the third color.

In an embodiment, the (N–1)th level shifter LS[N-1] of the (N–1)th portion CH[N-1] may be electrically connected to the (N–1)th latch portion LT[N-1]. The (N–1)th level shifter LS[N-1] may have substantially the same or similar function and structure as the first level shifter LS1. The (N–1)th latch portion LT[N-1] may have substantially the same or similar function and structure as the first latch portion LT1.

For example, the Nth portion CH[N] may include a (3N–2)th channel amplifier AMP[3N-2], a (3N–2)th digital-to-analog converter DAC[3N-2], and a (3N–2)th decoder DEC[3N-2], which output the data voltage VDATA to the (3N–2)th data line DL[3N-2]; a (3N–1)th channel amplifier AMP[3N-1], a (3N–1)th digital-to-analog converter DAC[3N-1], and a (3N–1)th decoder DEC[3N-1], which output the data voltage VDATA to the (3N–1)th data line DL[3N-1]; and a (3N)th channel amplifier AMP, a (3N)th digital-to-analog converter DAC, and a (3N)th decoder DEC, which output the data voltage VDATA to the (3N)th data line DL. The Nth portion CH[N] may further include an Nth latch portion LT[N].

In an embodiment, the (3N–2)th data line DL[3N-2] may be electrically connected to a sub-pixel, which emits light of the first color, the (3N–1)th data line DL[3N-1] may be electrically connected to a sub-pixel, which emits light of the second color, and the (3N)th data line DL may be electrically connected to a sub-pixel, which emits light of the third color.

In an embodiment, the Nth level shifter LS[N] of the Nth portion CH[N] may be electrically connected to the Nth latch portion LT[N]. The Nth level shifter LS[N] may have substantially the same or similar function and structure as the first level shifter LS1. The Nth latch portion LT[N] may have substantially the same or similar function and structure as the first latch portion LT1.

In addition, the second, third, …, (3N-1)th, and (3N)th channel amplifiers AMP2, AMP3, …, AMP[3N-1], AMP may have substantially the same structure and function as the first channel amplifier AMP1. The second, third, …, (3N-1)th, and (3N)th digital-to-analog converters DAC2, DAC3, …, DAC[3N-1], DAC may have substantially the same structure and function as the first digital-to-analog converter DAC1. The second, third, …, (3N-1)th, and (3N)th decoders DEC2, DEC3, …, DEC[3N-1], DEC may have substantially the same structure and function as the first decoder DEC1.

The bias voltage applier BIAS may output a first bias voltage VBG to the gamma driver GAMMA. The gamma driver GAMMA may output the first bias voltage VBG to the plurality of channel amplifiers AMP1, AMP2, …, AMP[3N-1], AMP included in the data driver 500. In addition, the gamma driver GAMMA may output the gamma reference voltage (e.g., the gamma reference voltage VGREF of FIG. 2) to the each of the plurality of digital-to-analog converters DAC1, DAC2, …, DAC[3N-1], DAC.

Each of the plurality of channel amplifiers AMP1, AMP2, …, AMP[3N-1], AMP may operate based on a second bias voltage VBA. For example, when the second bias voltage VBA is applied, each of the channel amplifiers AMP1, AMP2, …, AMP[3N-1], AMP may output a data voltage VDATA to one of the data lines DL1, DL2, …, DL[3N-1], DL corresponding to the channel amplifiers AMP1, AMP2, …, AMP[3N-1], AMP, respectively. For example, when the second bias voltage VBA is not applied, each of the channel amplifiers AMP1, AMP2, …, AMP[3N-1], AMP may be turned off. In such a case, the data voltage VDATA may not be applied to the data lines DL1, DL2, …, DL[3N-1], DL.

The data driver 500 may receive a high data power voltage AVDD and a low data power voltage AVSS. For example, the data driver 500 may generate the data voltage VDATA based on the high data power voltage AVDD and the low data power voltage AVSS. Specifically, the high data power voltage AVDD and the low data power voltage AVSS transmitted from the pad portion 700 of the display device 1 may be applied to the data driver 500. In other words, the high data power voltage AVDD and the low data power voltage AVSS may be voltages for driving the data driver 500. In this disclosure, one of the high data power voltage AVDD and the low data power voltage AVSS may be referred to as a “first data power voltage” and the other may be referred to as a “second data power voltage”.

The high data power voltage AVDD and the low data power voltage AVSS may be applied to each of the plurality of portions CH1, CH2, …, CH[N-1], CH[N]. For example, the high data power voltage AVDD and the low data power voltage AVSS may be applied to each of the plurality of channel amplifiers AMP1, AMP2, …, AMP[3N-1], AMP. For example, the high data power voltage AVDD and the low data power voltage AVSS may be applied to each of the plurality of digital-to-analog converters DAC1, DAC2, …, DAC[3N-1], DAC. For example, the high data power voltage AVDD and the low data power voltage AVSS may be applied to each of the plurality of decoders DEC1, DEC2, …, DEC[3N-1], DEC. For example, the high data power voltage AVDD and the low data power voltage AVSS may be applied to each of the plurality of level shifters LS1, LS2, …, LS[N-1], LS[N].

However, the display device 1 according to the embodiments of the disclosure may not be limited thereto. Although not shown in FIGS. 1 and 5, the display device 1 may further include a demultiplexer arranged in the non-display area NDA between the data driver 500 and the plurality of pixels PX.

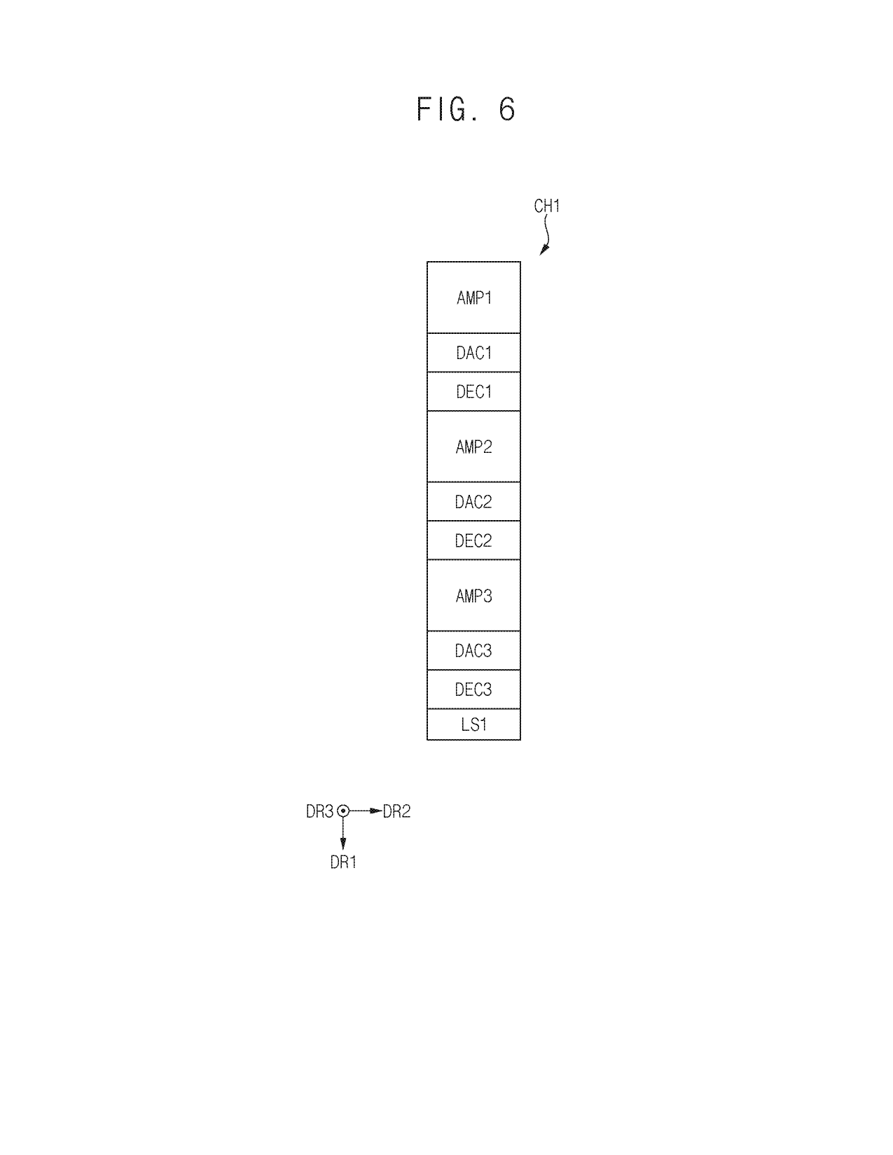

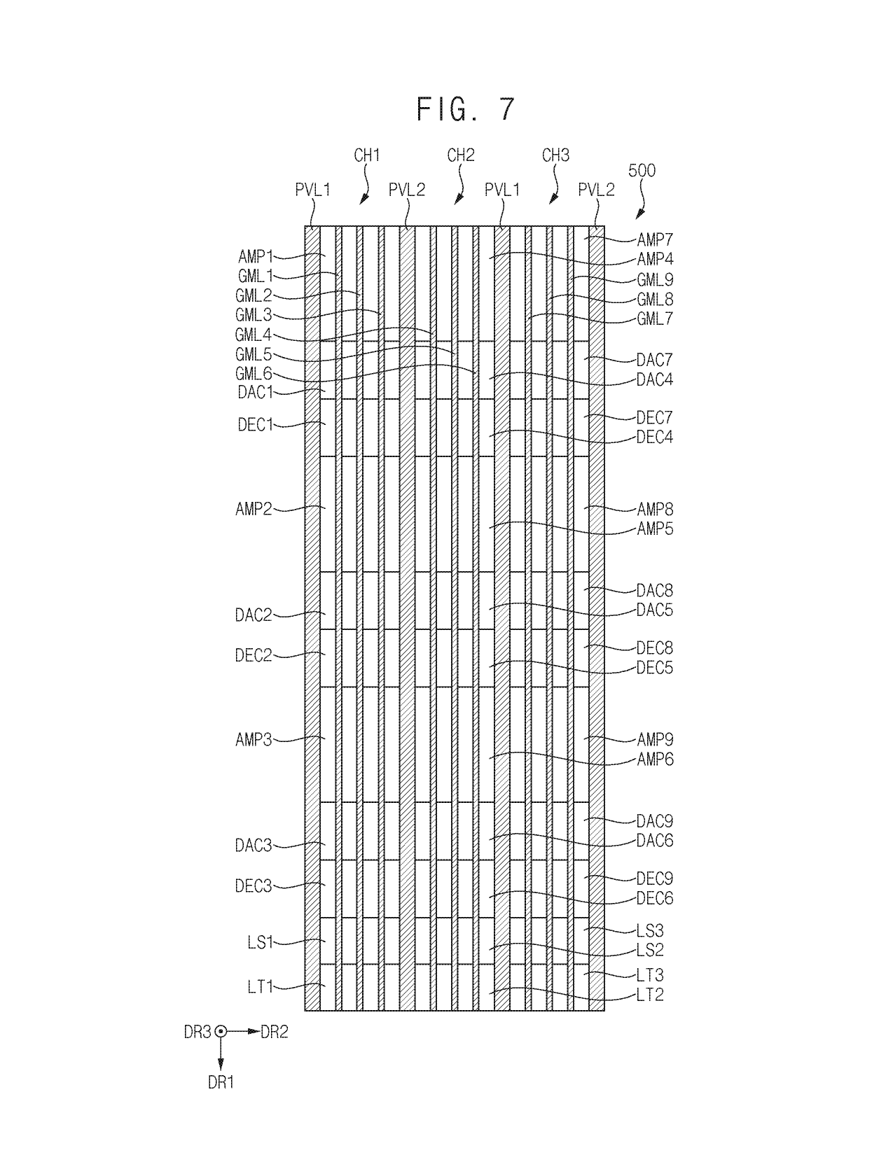

FIG. 6 is a plan view illustrating a first channel portion of FIG. 5. FIG. 7 is a plan view illustrating a data driver of FIG. 1.

Referring to FIG. 6, in the first channel portion CH1, the first channel amplifier AMP1, the first digital-to-analog converter DAC1, the first decoder DEC1, the second channel amplifier AMP2, the second digital-to-analog converter DAC2, the second decoder DEC2, a third channel amplifier AMP3, the third digital-to-analog converter DAC3, the third decoder DEC3, and the first level shifter LS1 may be arranged in order along the first direction DR1.

For example, the first digital-to-analog converter DAC1 may be arranged in the first direction DR1 from the first channel amplifier AMP1. The first decoder DEC1 may be arranged in the first direction DR1 from the first digital-to-analog converter DAC1. The second channel amplifier AMP2 may be arranged in the first direction DR1 from the first decoder DEC1. The second digital-to-analog converter DAC2 may be arranged in the first direction DR1 from the second channel amplifier AMP2. The second decoder DEC2 may be arranged in the first direction DR1 from the second digital-to-analog converter DAC2. The third channel amplifier AMP3 may be arranged in the first direction DR1 from the second decoder DEC2. The third digital-to-analog converter DAC3 may be arranged in the first direction DR1 from the third channel amplifier AMP3. The third decoder DEC3 may be arranged in the first direction DR1 from the third digital-to-analog converter DAC3. The first level shifter LS1 may be arranged in the first direction DR1 from the third decoder DEC3.

In an embodiment, a length of the first channel portion CH1 in the first direction DR1 may be greater than a length of the first channel portion CH1 in the second direction DR2. For example, the length of the first channel portion CH1 in the second direction DR2 may be about 5μm to about 20μm. Preferably, the length of the first channel portion CH1 in the second direction DR2 may be about 7μm to about 15μm. For example, the length of the first channel portion CH1 in the first direction DR1 may be about 600μm to about 1500μm. Preferably, the length of the first channel portion CH1 in the second direction DR1 may be about 800μm to about 1300μm.

In an embodiment, a length of the first channel amplifier AMP1 in the first direction DR1, a length of the second channel amplifier AMP2 in the first direction DR1, and a length of the third channel amplifier AMP3 in the first direction DR1, may be substantially the same. For example, each of a length of the first channel amplifier AMP1 in the first direction DR1, a length of the second channel amplifier AMP2 in the first direction DR1, and a length of the third channel amplifier AMP3 in the first direction DR1 may be about 150μm to about 350μm. Preferably, each of t a length of the first channel amplifier AMP1 in the first direction DR1, a length of the second channel amplifier AMP2 in the first direction DR1, and a length of the third channel amplifier AMP3 in the first direction DR1 may be about 200μm to about 320μm.

In an embodiment, a sum of the length of the first digital-to-analog converter DAC1 in the first direction DR1 and the length of the first decoder DEC1 in the first direction DR1 may be substantially a equal to a sum of the length of the second digital-to-analog converter DAC2 in the first direction DR1 and of the length of the second decoder DEC2 in the first direction DR1.

In an embodiment, a sum of the length of the first digital-to-analog converter DAC1 in the first direction DR1 and the length of the first decoder DEC1 in the first direction DR1 may be substantially equal to a sum of the length of the third digital-to-analog converter DAC3 in the first direction DR1 and the length of the third decoder DEC3 in the first direction DR1.

In an embodiment, the sum of the length of the second digital-to-analog converter DAC2 in the first direction DR1 and the length of the second decoder DEC2 in the first direction DR1 may be substantially equal to the sum of the length of the third digital-to-analog converter DAC3 in the first direction DR1 and the length of the third decoder DEC3 in the first direction DR1.

In an embodiment, a sum of the length of the first digital-to-analog converter DAC1 in the first direction DR1 and the length of the first decoder DEC1 in the first direction DR1 may be about 40μm to about 120μm. Preferably, the sum of the length of the first digital-to-analog converter DAC1 in the first direction DR1 and the length of the first decoder DEC1 in the first direction DR1 may be about 60μm to about 100μm.

In an embodiment, a sum of the length of the second digital-to-analog converter DAC2 in the first direction DR1 and the length of the second decoder DEC2 in the first direction DR1 may be about 40μm to about 120μm. Preferably, the sum of the length of the second digital-to-analog converter DAC2 in the first direction DR1 and the length of the second decoder DEC2 in the first direction DR1may be about 60μm to about 100μm.

In an embodiment, a sum of the of the third digital-to-analog converter DAC3 length in the first direction DR1 and the length of the third decoder DEC3 in the first direction DR1 may be about 40μm to about 120μm. Preferably, the sum of the length of the third digital-to-analog converter DAC3 in the first direction DR1 and the length of the third decoder DEC3 in the first direction DR1 may be about 60μm to about 100μm.

In an embodiment, a length of the first channel amplifier AMP1 in the first direction DR1 may be greater than a sum of the length of the first digital-to-analog converter DAC1 in the first direction DR1 and the length of the first decoder DEC1 in the first direction DR1.

In an embodiment, the length of the second channel amplifier AMP2 in the first direction DR1 may be greater than the sum of the length of the second digital-to-analog converter DAC2 in the first direction DR1 and the length of the second decoder DEC2 in the first direction DR1.

In an embodiment, the length of the third channel amplifier AMP3 in the first direction DR1 may be greater than a sum of the length of the third digital-to-analog converter DAC3 in the first direction DR1 and the length of the third decoder DEC3 in the first direction DR1.

In an embodiment, a length of the first level shifter LS1 in the first direction DR1 may be about 60μm to about 200μm. Preferably, the length of the first level shifter LS1 in the first direction DR1 may be about 100μm to about 160μm.

In an embodiment, the length of the first level shifter LS1 in the first direction DR1 may be smaller than the length of the first channel amplifier AMP1 in the first direction DR1. In an embodiment, the length of the first level shifter LS1 in the first direction DR1 may be smaller than the length of the second channel amplifier AMP2 in the first direction DR1. In an embodiment, the length of the first level shifter LS1 in the first direction DR1 may be smaller than the length of the third channel amplifier AMP3 in the first direction DR1.

In an embodiment, the length of the first level shifter LS1 in the first direction DR1 may be greater than a sum of the length of the first digital-to-analog converter DAC1 in the first direction DR1 and the length of the first decoder DEC1 in the first direction DR1. In an embodiment, the length of the first level shifter LS1 in the first direction DR1 may be greater than a sum of the length of the second digital-to-analog converter DAC2 in the first direction DR1 and the length of the second decoder DEC2 in the first direction DR1. In an embodiment, the length of the first level shifter LS1 in the first direction DR1 may be greater than a sum of the length x of the third digital-to-analog converter DAC3 in the first direction DR1 and the length of the third decoder DEC3 in the first direction DR1.

Referring further to FIGS. 1 and 5, in an embodiment, in a plan view, the first channel amplifier AMP1 may be located relatively close to the display area DA, and the first level shifter LS1 may be located relatively close to the gamma reference voltage generator 400.

A structure of the first channel portion CH1 is illustrated in FIG. 6, the second, third, (N-1)th, and Nth channel portions CH2, …, CH[N-1], CH[N] of FIG. 5 may have a structure that is substantially the same as the structure of the first channel portion CH1.

Referring to FIGS. 1 and 7, the data driver 500 may include a first data power voltage line PVL1 and a second data power voltage line PVL2, each electrically connected to the first channel portion CH1, the second channel portion CH2, and the third channel portion CH3. The data driver 500 may further include a first gamma voltage line GML1, a second gamma voltage line GML2, a third gamma voltage line GML3, a fourth gamma voltage line GML4, a fifth gamma voltage line GML5, a sixth gamma voltage line GML6, a seventh gamma voltage line GML7, an eighth gamma voltage line GML8, and a ninth gamma voltage line GML9. The data driver 500 may further include a third latch portion LT3 electrically connected to the third channel portion CH3.

In this disclosure, at least one gamma voltage line among the first gamma voltage line GML1, the second gamma voltage line GML2, and the third gamma voltage line GML3 may be referred to as the first gamma voltage line. In addition, at least one gamma voltage line among the fourth gamma voltage line GML4, the fifth gamma voltage line GML5, and the sixth gamma voltage line GML6 may be referred to as the second gamma voltage line. Also, at least one gamma voltage line among the seventh gamma voltage line GML7, the eighth gamma voltage line GML8, and the ninth gamma voltage line GML9 may be referred to as the third gamma voltage line.

The third channel portion CH3 may include a seventh channel amplifier AMP7, a seventh digital-to-analog converter DAC7, a seventh decoder DEC7, an eighth channel amplifier AMP8, an eighth digital-to-analog converter DAC8, an eighth decoder DEC8, a ninth channel amplifier AMP9, a ninth digital-to-analog converter DAC9, a ninth decoder DEC9, and a third level shifter LS3.

In an embodiment, a high data power voltage AVDD may be applied to the first data power voltage line PVL1, and a low data power voltage AVSS may be applied to the second data power voltage line PVL2. In another embodiment, a low data power voltage AVSS may be applied to the first data power voltage line PVL1, and a high data power voltage AVDD may be applied to the second data power voltage line PVL2.

In an embodiment, the first data power voltage line PVL1 may be arranged on the first channel portion CH1, the second channel portion CH2, and the third channel portion CH3. In an embodiment, the second data power voltage line PVL2 may be arranged on the first channel portion CH1, the second channel portion CH2, and the third channel portion CH3. In an embodiment, the first data power voltage line PVL1 may be arranged on the first latch portion LT1, the second latch portion LT2, and the third latch portion LT3. In an embodiment, the second data power voltage line PVL2 may be arranged on the first latch portion LT1, the second latch portion LT2, and the third latch portion LT3.

In an embodiment, the first data power voltage line PVL1 may extend along the first direction DR1. The first data power voltage line PVL1 may overlap, in a plan view, with portions of the first channel portion CH1 and the first latch portion LT1. For example, the first data power voltage line PVL1 may overlap, in a plan view, with one side of each of the first channel portion CH1 and the first latch portion LT1. Specifically, the first data power voltage line PVL1 may overlap, in a plan view, with the side of each of the first channel portion CH1 and the first latch portion LT1, which faces the opposite direction of the second direction DR2.

In an embodiment, the first data power voltage line PVL1 may overlap, in a plan view, with the first channel amplifier AMP1, the first digital-to-analog converter DAC1, the first decoder DEC1, the second channel amplifier AMP2, the second digital-to-analog converter DAC2, the second decoder DEC2, the third channel amplifier AMP3, the third digital-to-analog converter DAC3, the third decoder DEC3, and the first latch portion LT1, and may extend along the first direction DR1.

Referring further to FIG. 4, the first data power voltage line PVL1 may be arranged between the pixel electrode PXE and the source and drain electrodes SE and DE in a cross-sectional view. For example, the first data power voltage line PVL1 may be arranged in the same layer as the fourth connection electrode CE4. Specifically, the first data power voltage line PVL1 may include the same material as the fourth connection electrode CE4 and may be formed through the same process as the fourth connection electrode CE4. However, the arrangement of the first data power voltage line PVL1 according to the embodiments of the present disclosure may not be limited thereto, and in another embodiment, the first data power voltage line PVL1 may be arranged in the same layer as one of the first, second, and third connection electrodes CE1, CE2, and CE3.

In an embodiment, the conductive layers included in the first channel portion CH1 may be arranged in the same layer as the gate electrode GE, the source and drain electrodes SE and DE, and the first connection electrode CE1. For example, the conductive layers included in the first channel amplifier AMP1 may be arranged on the same layer as the gate electrode GE, the source and drain electrodes SE and DE, and the first connection electrode CE1. Structures of the second and third channel portions CH2 and CH3 may be substantially same as a structure of the first channel portion CH1.

In an embodiment, the first data power voltage line PVL1 may be electrically connected to each of the first channel portion CH1 and the first latch portion LT1. For example, the first data power voltage line PVL1 may be electrically connected to each of the first channel portion CH1 and the first latch portion LT1 through a contact hole penetrating at least one of the first, second, third, fourth, and fifth insulating layers IL1, IL2, IL3, IL4, and IL5 in a thickness direction (e.g., the third direction DR3).

In an embodiment, the second data power voltage line PVL2 may extend along a first direction DR1. The second data power voltage line PVL2 may overlap in a plan view with a portion of each of the first channel portion CH1 and the first latch portion LT1. For example, the second data power voltage line PVL2 may overlap in a plan view with another side of each of the first channel portion CH1 and the first latch portion LT1 opposite to said one side. Specifically, the second data power voltage line PVL2 may overlap in a plan view with a side of each of the first channel portion CH1 and the first latch portion LT1 facing a second direction DR2.

In an embodiment, the second data power voltage line PVL2 may overlap in a plan view with the first channel amplifier AMP1, the first digital-to-analog converter DAC1, the first decoder DEC1, the second channel amplifier AMP2, the second digital-to-analog converter DAC2, the second decoder DEC2, the third channel amplifier AMP3, the third digital-to-analog converter DAC3, the third decoder DEC3, and the first latch portion LT1, and may extend along the first direction DR1.

The second data power voltage line PVL2 may overlap in a plan view with a portion of each of the second channel portion CH2 and the second latch portion LT2. For example, the second data power voltage line PVL2 may overlap in a plan view with one side of each of the second channel portion CH2 and the second latch portion LT2. Specifically, the second data power voltage line PVL2 may overlap in a plan view with a side of each of the second channel portion CH2 and the second latch portion LT2 facing an opposite direction of the second direction DR2.

In an embodiment, the second data power voltage line PVL2 may overlap in a plan view with the first channel portion CH1 and the second channel portion CH2. In an embodiment, one second data power voltage line PVL2 may be electrically connected to each of the first channel portion CH1 and the second channel portion CH2. In an embodiment, the second data power voltage line PVL2 may be arranged in a plan view between the first channel portion CH1 and the second channel portion CH2.

In an embodiment, the second data power voltage line PVL2 may overlap in a plan view with the first latch portion LT1 and the second latch portion LT2 at the same time. In an embodiment, one second data power voltage line PVL2 may be electrically connected to each of the first latch portion LT1 and the second latch portion LT2.

In other words, the first channel portion CH1 and the second channel portion CH2, which are adjacent to each other in a plan view, may share one second data power voltage line PVL2. In an embodiment, the first channel portion CH1 and the second channel portion CH2 may be symmetrical with respect to the second data power voltage line PVL2.

In an embodiment, the second data power voltage line PVL2 adjacent to the second channel portion CH2 may overlap in a plan view with the fourth channel amplifier AMP4, the fourth digital-to-analog converter DAC4, the fourth decoder DEC4, the fifth channel amplifier AMP5, the fifth digital-to-analog converter DAC5, the fifth decoder DEC5, the sixth channel amplifier AMP6, the sixth digital-to-analog converter DAC6, the sixth decoder DEC6, and the second latch portion LT2, and may extend along the first direction DR1.

In a cross-sectional view, the second data power voltage line PVL2 may be arranged between the pixel electrode PXE and the source and drain electrodes SE and DE. For example, the second data power voltage line PVL2 may be arranged in the same layer as the fourth connection electrode CE4. Specifically, the second data power voltage line PVL2 may include the same material as the fourth connection electrode CE4 and may be formed through the same process as the fourth connection electrode CE4. However, the arrangement of the second data power voltage line PVL2 according to the embodiments of the present disclosure may not be limited thereto, and the second data power voltage line PVL2 may also be arranged in the same layer as one of the first to third connection electrodes CE1, CE2, or CE3. In an embodiment, the first data power voltage line PVL1 and the second data power voltage line PVL2 may be arranged in the same layer.

In an embodiment, the second data power voltage line PVL2 may be electrically connected to each of the second channel portion CH2 and the second latch portion LT2. For example, the second data power voltage line PVL2 may be electrically connected to each of the second channel portion CH2 and the second latch portion LT2 through a contact hole penetrating at least one of the first to fifth insulating layers IL1, IL2, IL3, IL4, IL5 in the thickness direction (e.g., the third direction DR3).

The first data power voltage line PVL1 may overlap in a plan view with a portion of each of the second channel portion CH2 and the second latch portion LT2. For example, the first data power voltage line PVL1 may overlap in a plan view with a side of each of the second channel portion CH2 and the second latch portion LT2 opposite to the above-mentioned side. Specifically, the first data power voltage line PVL1 may overlap in a plan view with a side of each of the second channel portion CH2 and the second latch portion LT2 facing the second direction DR2.

In an embodiment, the first data power voltage line PVL1 adjacent to the second channel portion CH2 may overlap in a plan view with the fourth channel amplifier AMP4, the fourth digital-to-analog converter DAC4, the fourth decoder DEC4, the fifth channel amplifier AMP5, the fifth digital-to-analog converter DAC5, the fifth decoder DEC5, the sixth channel amplifier AMP6, the sixth digital-to-analog converter DAC6, the sixth decoder DEC6, and the second latch portion LT2, and may extend along the first direction DR1.

The first data power voltage line PVL1 may overlap in a plan view with a portion of each of the third channel portion CH3 and the third latch portion LT3. For example, the first data power voltage line PVL1 may overlap in a plan view with one side of each of the third channel portion CH3 and the third latch portion LT3. Specifically, the first data power voltage line PVL1 may overlap in a plan view with a side of each of the third channel portion CH3 and the third latch portion LT3 facing the opposite direction of the second direction DR2.

In an embodiment, the first data power voltage line PVL1 may overlap in a plan view with the second channel portion CH2 and the third channel portion CH3. In an embodiment, one first data power voltage line PVL1 may be electrically connected to each of the second channel portion CH2 and the third channel portion CH3. In an embodiment, the first data power voltage line PVL1 may be arranged in a plan view between the second channel portion CH2 and the third channel portion CH3.

In an embodiment, the first data power voltage line PVL1 may overlap in a plan view with the second latch portion LT2 and the third latch portion LT3. In an embodiment, one first data power voltage line PVL1 may be electrically connected to each of the second latch portion LT2 and the third latch portion LT3.

In other words, the second channel portion CH2 and the third channel portion CH3, which are adjacent to each other in a plan view, may share one first data power voltage line PVL1. In an embodiment, the second channel portion CH2 and the third channel portion CH3 may be symmetrical with respect to the first data power voltage line PVL1.

In an embodiment, the first data power voltage line PVL1 adjacent to the third channel portion CH3 may overlap in a plan view with the seventh channel amplifier AMP7, the seventh digital-to-analog converter DAC7, the seventh decoder DEC7, the eighth channel amplifier AMP8, the eighth digital-to-analog converter DAC8, the eighth decoder DEC8, the ninth channel amplifier AMP9, the ninth digital-to-analog converter DAC9, the ninth decoder DEC9, and the third latch portion LT3, and may extend along the first direction DR1.

In an embodiment, the first data power voltage line PVL1 and the second data power voltage line PVL2 may be spaced apart from each other in a plan view. For example, the first data power voltage line PVL1 and the second data power voltage line PVL2 may be spaced apart from each other in the second direction DR2. In addition, a plurality of first data power voltage lines and a plurality of second data power voltage lines may be alternately arranged along the second direction DR2.

Accordingly, two channel portions, which are adjacent to both sides of the first data power voltage line PVL1 and are disposing the first data power voltage line PVL1 between the two channel portions, may be electrically connected to the first data power voltage line PVL1. In addition, two channel portions, which are adjacent to both sides of the second data power voltage line PVL2 and are disposing the second data power voltage line PVL2 between the two channel portions, may be electrically connected to the second data power voltage line PVL2.

In addition, the two channel portions adjacent to both sides of the first data power voltage line PVL1 may be symmetrical with respect to the first data power voltage line PVL1. Similarly, the two channel portions adjacent to both sides of the second data power voltage line PVL2 may be symmetrical with respect to the first data power voltage line PVL1.

In an embodiment, each of the first gamma voltage line GML1, the second gamma voltage line GML2, and the third gamma voltage line GML3 may extend in the first direction DR1. Each of the first gamma voltage line GML1, the second gamma voltage line GML2, and the third gamma voltage line GML3 may be arranged between the first data power voltage line PVL1 and the second data power voltage line PVL2 in a plan view.

In an embodiment, each of the first gamma voltage line GML1, the second gamma voltage line GML2, and the third gamma voltage line GML3 may be electrically connected to the first channel portion CH1. For example, the first gamma voltage line GML1 may be electrically connected to the first channel amplifier AMP1, the first digital-to-analog converter DAC1, and the first decoder DEC1. The second gamma voltage line GML2 may be electrically connected to the second channel amplifier AMP2, the second digital-to-analog converter DAC2, and the second decoder DEC2. The third gamma voltage line GML3 may be electrically connected to the third channel amplifier AMP3, the third digital-to-analog converter DAC3, and the third decoder DEC3.

Specifically, the gamma reference voltage VGREF associated with the first sub-pixel SPX1, which emits light of the first color may be applied to the first gamma voltage line GML1. The gamma reference voltage VGREF associated with the second sub-pixel SPX2, which emits light of the second color may be applied to the second gamma voltage line GML2. The gamma reference voltage VGREF associated with the third sub-pixel SPX3, which emits light of the third color may be applied to the third gamma voltage line GML3.

In an embodiment, the first gamma voltage line GML1, the second gamma voltage line GML2, and the third gamma voltage line GML3 may be arranged in the same layer as the first data power voltage line PVL1 and the second data power voltage line PVL2. In an embodiment, the first gamma voltage line GML1, the second gamma voltage line GML2, and the third gamma voltage line GML3 may be spaced apart from each other in a plan view. For example, the first gamma voltage line GML1, the second gamma voltage line GML2, and the third gamma voltage line GML3 may be spaced apart in the second direction DR2 in a plan view.

In an embodiment, the first gamma voltage line GML1, the second gamma voltage line GML2, and the third gamma voltage line GML3 may extend from the gamma reference voltage generator 400. For example, the first gamma voltage line GML1, the second gamma voltage line GML2, and the third gamma voltage line GML3 may extend from the gamma reference voltage generator 400 toward the data driver 500.

The fourth gamma voltage line GML4 and the seventh gamma voltage line GML7 may be substantially same as the first gamma voltage line GML1. The fifth gamma voltage line GML5 and the eighth gamma voltage line GML8 may be substantially same as the second gamma voltage line GML2. The sixth gamma voltage line GML6 and the ninth gamma voltage line GML9 may be substantially same as the third gamma voltage line GML3.

However, the number of gamma voltage lines included in the data driver 500 according to the embodiments of the present disclosure may not be limited thereto, and the number of gamma voltage lines connected to one channel portion may be two or less or four or more.

As described above, in the display device 1 according to an embodiment of the present disclosure, one data power voltage line may be electrically connected to each of two channel portions. In addition, one data power voltage line may extend in the first direction DR1 and may overlap in a plan view with the two channel portions. Moreover, the data power voltage lines to which the high data power voltage AVDD is applied and the data power voltage lines to which the low data power voltage AVSS is applied may be alternately arranged along the second direction DR2. Accordingly, a number of channel portions electrically connected to a plurality of pixels PX in the display device 1 may be increased, and a number of pixels PX electrically connected to each of the channel portions may also be increased. Therefore, display device 1 for a high-resolution may be implemented.

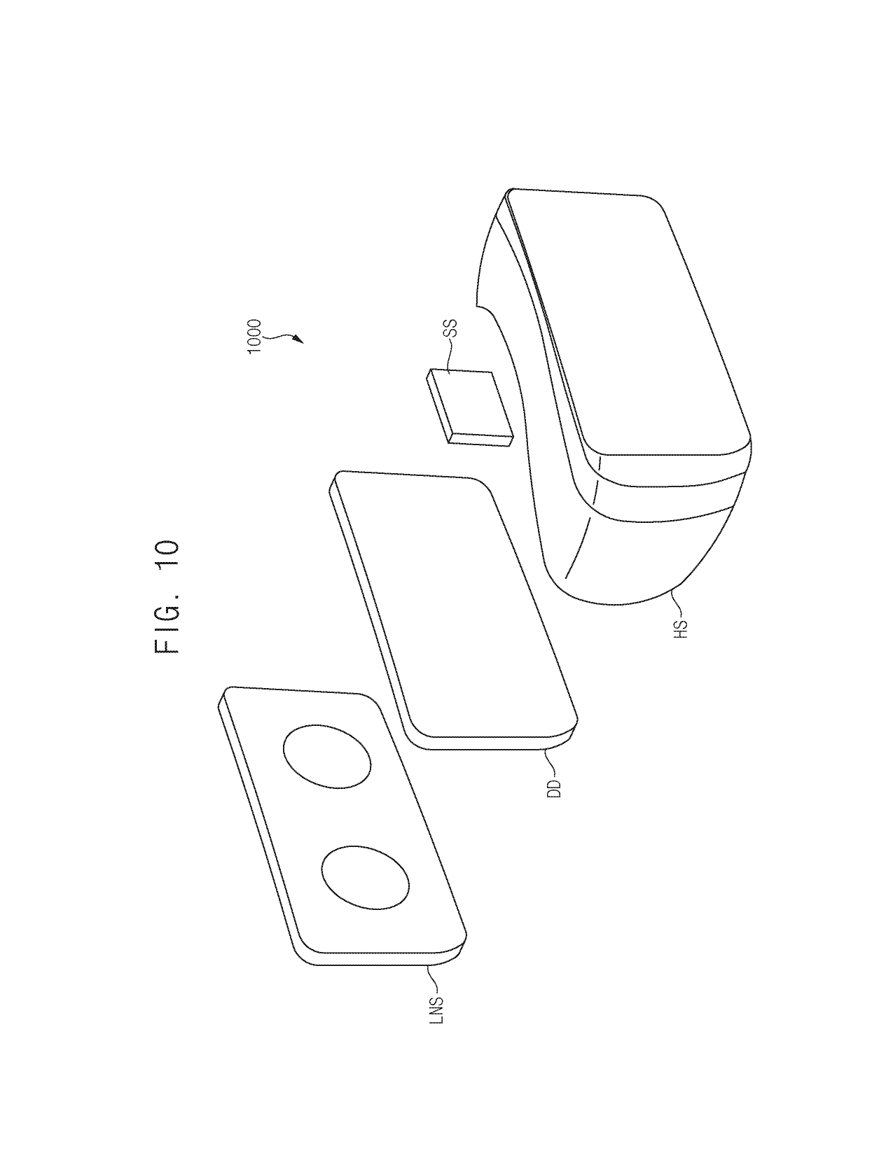

FIG. 8 is a block diagram illustrating an electronic device according to an embodiment of the present disclosure. FIG. 9 is a view illustrating an example in which the electronic device of FIG. 8 is implemented as a smartphone. FIG. 10 is a view illustrating an example in which the electronic device of FIG. 8 is implemented as a head-mounted device.

Referring to FIG. 8, an electronic device 1000 may include a processor 1010, a memory device 1020, a storage device 1030, an input/output device 1040, a power supply 1050, and a display device 1060. When the electronic device 1000 includes the display device 1060, the display device 1060 may be the display device 1 of FIG. 1. The electronic device 1000 may further include various ports, which may communicate with a video card, sound card, memory card, USB device, and the like, or may communicate with other systems.

In an embodiment, the electronic device 1000 may be implemented as a smartphone. However, the type of the electronic device 1000 according to embodiments of the present disclosure may be exemplary and may not be limited thereto. For example, the electronic device 1000 may be implemented as a mobile phone, video phone, smart pad, smart watch, tablet PC, in-vehicle navigation system, computer monitor, notebook, head-mounted display device, and the like.

In an embodiment, the processor 1010 may be a microprocessor, a central processing unit (CPU), or an application processor. The processor 1010 may be connected to other components via an address bus, control bus, data bus, and the like. According to the embodiment, the processor 1010 may also be connected to an expansion bus such as a Peripheral Component Interconnect (PCI) bus.

In an embodiment, the processor 1010 may output input image data IMG and input control signals CONT to the driving controller 200 of FIG. 2. Accordingly, the display device 1060 may be driven based on the input image data IMG and the input control signals CONT.

In an embodiment, the memory device 1020 may store data for the operation of the electronic device 1000. For example, the memory device 1020 may include nonvolatile memory devices such as Erasable Programmable Read-Only Memory (EPROM) devices, Electrically Erasable Programmable Read-Only Memory (EEPROM) devices, flash memory devices, Phase Change Random Access Memory (PRAM) devices, Resistance Random Access Memory (RRAM) devices, Nano Floating Gate Memory (NFGM) devices, Polymer Random Access Memory (PoRAM) devices, Magnetic Random Access Memory (MRAM) devices, Ferroelectric Random Access Memory (FRAM) devices, and the like, and/or volatile memory devices such as Dynamic Random Access Memory (DRAM) devices, Static Random Access Memory (SRAM) devices, mobile DRAM devices, and the like.

In an embodiment, the storage device 1030 may include a Solid State Drive (SSD), a Hard Disk Drive (HDD), a CD-ROM, and the like.

In an embodiment, the input/output device 1040 may include input means such as a keyboard, keypad, touchpad, touchscreen, mouse, and output means such as a speaker, printer, and the like.

In an embodiment, the display device 1060 may be included in the input/output device 1040. However, the relationship between the input/output device 1040 and the display device 1060 according to embodiments of the present disclosure may not be limited thereto. In an embodiment, the power supply 1050 may supply power for the operation of the electronic device 1000. In an embodiment, the display device 1060 may be connected to other components through the buses or other communication links.

Referring to FIG. 9, in an embodiment, the electronic device 1000 may be implemented as a smartphone. Referring to FIG. 10, in an embodiment, the electronic device 1000 may be implemented as a head-mounted device. The electronic device 1000 may include a lens portion LNS, a display device DD, a sensor portion SS, and a housing HS. In an embodiment, the electronic device 1000 may be a virtual reality (VR) device, an augmented reality (AR) device, a mixed reality (MR) device, or an extended reality (XR) device that is worn on the user's head. The display device DD may be the display device 1 of FIG. 1 or the display device 1060 of FIG. 8.

In an embodiment, the sensor portion SS may include a camera, but may not be limited thereto and may include various types of sensors capable of tracking the user's gaze. The display device DD may be arranged adjacent to the lens portion LNS. The housing HS may accommodate the lens portion LNS, the display device DD, and the sensor portion SS. In an embodiment, the housing HS may accommodate the processor, the memory device, the storage device, the input/output device, and the power supply described in FIG. 8. Accordingly, the housing HS may provide a durable electronic device 1000 to the user.

In FIG. 10, the lens portion LNS, the display device DD, and the sensor portion SS are shown as being housed on one side of the housing HS, but the electronic device 1000 according to embodiments of the present disclosure may not be limited thereto. In an embodiment, the electronic device 1000 may further include a strap portion for being worn on the user’s head, a cushion portion for enhancing wearing comfort, and the like. Accordingly, the electronic device 1000 may provide stable wearability to the user.

However, the electronic device 1000 described with reference to FIGS. 9 and 10 is merely exemplary, and the type of the electronic device 1000 according to embodiments of the present disclosure may not be limited thereto. For example, the electronic device 1000 may be implemented as a mobile phone, video phone, smart pad, smart watch, tablet PC, vehicle display, computer monitor, notebook, and the like. The electronic device 1000 may also be a television, a monitor, a notebook computer, a tablet, and the like. In addition, the electronic device 1000 may be a vehicle.

As described above, in the electronic device 1000 according to embodiments of the present disclosure, the processor 1010 for driving the display device 1060 may be included, and the housing HS for accommodating the display device 1060 or the display device DD may be provided. Accordingly, the electronic device 1000 capable of operating stably and displaying high-resolution images may be provided.

The devices according to the embodiments may be applied to a display device included in a computer, a notebook, a mobile phone, a smartphone, a smart pad, a PMP, a PDA, an MP3 player, or the like.

Although the devices according to the embodiments have been described with reference to the drawings, the illustrated embodiments are examples, and may be modified and changed by a person having ordinary knowledge in the relevant technical field without departing from the technical spirit described in the following claims.

What is claimed is:

1. A display device comprising:
a substrate including a display area and a non-display area adjacent to the display area;
a plurality of pixels arranged in the display area on the substrate;
a first channel portion arranged in the non-display area on the substrate and, which provides a data voltage to a first pixel among the plurality of pixels;
a second channel portion arranged in the non-display area on the substrate, spaced apart from the first channel portion in a plan view, and, which provides the data voltage to a second pixel, which is different from the first pixel, among the plurality of pixels; and
a first data power voltage line arranged between the first channel portion and the second channel portion in the plan view, overlapping the first channel portion and the second channel portion in the plan view, and electrically connected to each of the first channel portion and the second channel portion.

2. The display device of claim 1, wherein the first data power voltage line extends along a first direction, and
the second channel portion is spaced apart from the first channel portion in a second direction crossing the first direction.

3. The display device of claim 2, further comprising:
a third channel portion spaced apart from the second channel portion in the second direction, disposed opposite to the first channel portion with respect to the second channel portion, and, which provides the data voltage to a third pixel, which is different from the first pixel and the second pixel, among the plurality of pixels; and
a second data power voltage line arranged between the second channel portion and the third channel portion in the plan view and electrically connected to each of the second channel portion and the third channel portion.

4. The display device of claim 3, wherein a first data power voltage is configured to be applied to the first data power voltage line, and
a second data power voltage, which has a different level from the first data power voltage, is configured to be applied to the second data power voltage line.

5. The display device of claim 3, wherein the second data power voltage line overlaps the second channel portion and the third channel portion in the plan view.

6. The display device of claim 3, wherein each of the first data power voltage line and the second data power voltage line is provided in plurality, and the first data power voltage line and the second data power voltage line are alternately arranged along the second direction.

7. The display device of claim 3, wherein the second channel portion and the third channel portion are symmetrical with respect to the second data power voltage line.

8. The display device of claim 3, further comprising:
at least one transistor arranged in the display area, the at least one transistor each including a gate electrode and source and drain electrodes arranged on the gate electrode; and
a light-emitting element arranged in the display area, electrically connected to each of the at least one transistor, and including a pixel electrode, a light-emitting layer, and a common electrode sequentially stacked,
wherein the first data power voltage line and the second data power voltage line are arranged, in a cross-sectional view, between the pixel electrode and the source and drain electrodes.

9. The display device of claim 3, further comprising:
a gamma reference voltage generator arranged in the non-display area on the substrate and, which provides a gamma reference voltage to each of the first channel portion and the second channel portion;
at least one first gamma voltage line extending from the gamma reference voltage generator toward the first channel portion;
at least one second gamma voltage line extending from the gamma reference voltage generator toward the second channel portion; and
at least one third gamma voltage line extending from the gamma reference voltage generator toward the third channel portion.

10. The display device of claim 9, wherein the at least one first gamma voltage line overlaps the first channel portion in the plan view,
the at least one second gamma voltage line overlaps the second channel portion in the plan view, and
the at least one third gamma voltage line overlaps the third channel portion in the plan view.

11. The display device of claim 9, further comprising:
at least one transistor arranged in the display area, the at least one transistor each including a gate electrode, and source and drain electrodes arranged on the gate electrode; and
a light-emitting element arranged in the display area, electrically connected to each of the at least one transistor, and including a pixel electrode, a light-emitting layer, and a common electrode sequentially stacked,
wherein the first gamma voltage line, the second gamma voltage line, and the third gamma voltage line are arranged, in a cross-sectional view, between the pixel electrode and the source and the drain electrodes.

12. The display device of claim 9, wherein each of the first gamma voltage line, the second gamma voltage line, and the third gamma voltage line is arranged between the first data power voltage line and the second data power voltage line in the plan view.

13. The display device of claim 1, wherein the first channel portion and the second channel portion are symmetrical with respect to the first data power voltage line.

14. The display device of claim 1, wherein the first pixel includes:
a first sub-pixel, which emits light of a first color;
a second sub-pixel, which emits light of a second color different from the first color; and
a third sub-pixel, which emits light of a third color different from the second color,
and the first channel portion includes:
a first channel amplifier arranged in the non-display area adjacent to the display area on the substrate and, which outputs the data voltage to the first sub-pixel;
a second channel amplifier spaced apart from the first channel amplifier in a first direction and, which outputs the data voltage to the second sub-pixel; and
a third channel amplifier spaced apart from the second channel amplifier in the first direction and, which outputs the data voltage to the third sub-pixel.

15. The display device of claim 14, wherein the first channel portion further includes:
a first digital-to-analog converter arranged between the first channel amplifier and the second channel amplifier, in the plan view;
a first decoder arranged between the first digital-to-analog converter and the second channel amplifier, in the plan view;
a second digital-to-analog converter arranged between the second channel amplifier and the third channel amplifier, in the plan view;
a second decoder arranged between the second digital-to-analog converter and the third channel amplifier, in the plan view;
a third digital-to-analog converter located in the first direction from the third channel amplifier, in the plan view; and
a third decoder located in the first direction from the third digital-to-analog converter in the plan view.

16. The display device of claim 15, wherein a length of the first channel amplifier in the first direction is greater than a sum of a length of the first digital-to-analog converter in the first direction and a length of the first decoder in the first direction.

17. The display device of claim 15, wherein a length of the first channel amplifier in the first direction, a length of the second channel amplifier in the first direction, and a length of the third channel amplifier in the first direction are equal to each other.

18. The display device of claim 1, wherein the first data power voltage line is arranged on the first channel portion and the second channel portion.

19. An electronic device comprising:
a processor, which outputs an input image data and an input control signal; and
a display device, which is drove based on the input image data and the input control signal,
wherein the display device includes:
a substrate including a display area and a non-display area adjacent to the display area;
a plurality of pixels arranged in the display area on the substrate;
a first channel portion arranged in the non-display area on the substrate and, which provides a data voltage to a first pixel among the plurality of pixels;
a second channel portion arranged in the non-display area on the substrate, spaced apart from the first channel portion in a plan view, and, which provides the data voltage to a second pixel, which is different from the first pixel, among the plurality of pixels; and
a first data power voltage line arranged between the first channel portion and the second channel portion in the plan view, overlapping the first channel portion and the second channel portion in the plan view, and electrically connected to each of the first channel portion and the second channel portion.

20. The electronic device of claim 19, wherein the electronic device is one selected from a group consisted of a virtual reality (VR) device, an augmented reality (AR) device, a mixed reality (MR) device, an extended reality (XR) device, a head-mounted device, a mobile phone, a video phone, a smartphone, a smart pad, a smart watch, a tablet PC, a vehicle display, a television, a monitor, a notebook computer, or a vehicle.
